(19) United States
(12) Patent Application Publication
(10) Pub. No.: US 2025/0063934 A1
(43) Pub. Date: Feb. 20, 2025

(54) DISPLAY APPARATUS

(71) Applicant: Samsung Display Co., Ltd., Yongin-Si (KR)

(72) Inventors: Kyungmin Kim, Yongin-si (KR); Junkyul Song, Yongin-si (KR); Seongwon Kim, Yongin-si (KR); Hosik Shin, Yongin-si (KR); Gyujeong Lee, Yongin-si (KR)

(21) Appl. No.: 18/800,132

(22) Filed: Aug. 12, 2024

(30) Foreign Application Priority Data
Aug. 18, 2023 (KR) 10-2023-0108267

(51) Int. Cl. H10K 77/10; H01L 23/538; H01L 33/52; H01L 33/60; H10K 59/80; H10K 59/88; H10K 102/00

(52) U.S. Cl. CPC H10K 77/111; H01L 23/5387; H01L 33/52; H01L 33/60; H10K 59/873; H10K 59/877; H10K 59/878; H10K 59/88; H01L 2933/0091; H10K 2102/311

(57) ABSTRACT

A display apparatus includes a substrate including island portions spaced apart from each other, a bridge portions connecting the island portions to each other, openings disposed between island portions, at least one light-emitting element arranged in each of the island portions, first encapsulation layers disposed on the island portions, respectively, each of the first encapsulation layers sealing the at least one light-emitting element, a second encapsulation layer disposed on the first encapsulation layers to cover the first encapsulation layer, sealing the plurality of island portions and the bridge portions, and filling at least an upper portion of the openings, a lower encapsulation layer disposed under the substrate, and a lower adhesive layer arranged between the lower encapsulation layer and the substrate, wherein the lower adhesive layer fills at least a portion of a lower portion of the openings.

### CROSS-REFERENCE TO RELATED APPLICATION

This application is based on and claims priority under 35 U.S.C. § 119 to Korean Patent Application No. 10-2023-0108267, filed on Aug. 18, 2023, in the Korean Intellectual Property Office, the disclosure of which is incorporated by reference herein in its entirety.

### BACKGROUND

### 1. Field

One or more embodiments relate to a display apparatus such as a stretchable display apparatus.

### 2. Description of the Related Art

With the development of display apparatuses that visually display electrical signals, various display apparatuses with excellent characteristics such as thinness, light weight, and low power consumption have been introduced. For example, flexible display apparatuses that can be folded or rolled have been developed. Recently, there has been a lot of research and development on stretchable display apparatuses that can change into different shapes.

### SUMMARY

One or more embodiments include a flexible display apparatus such as a stretchable display apparatus.

Additional aspects will be set forth in part in the description which follows and, in part, will be apparent from the description, or may be learned by practice of the presented embodiments of the disclosure.

According to one or more embodiments, a display apparatus includes a substrate including a plurality of island portions spaced apart from each other, a plurality of bridge portions connecting the plurality of island portions to each other, a plurality of openings disposed between the plurality of island portions, at least one light-emitting element arranged in each of the plurality of island portions, a plurality of first encapsulation layers disposed on the plurality of island portions, respectively, each of the plurality of first encapsulation layers sealing the at least one light-emitting element, a second encapsulation layer disposed on the plurality of first encapsulation layers to cover the plurality of island portions and the plurality of bridge portions and filling at least upper portions of the plurality of openings, a lower encapsulation layer disposed under the substrate, and a lower adhesive layer arranged between the lower encapsulation layer and the substrate, wherein the lower adhesive layer fills at least lower portions of the plurality of openings.

In an embodiment, a modulus of the second encapsulation layer may be less than a modulus of the first encapsulation layer.

In an embodiment, the modulus of the second encapsulation layer may be about 100 kPa to about 5 MPa.

In an embodiment, a modulus of the lower encapsulation layer may be less than a modulus of the first encapsulation layer.

In an embodiment, the display apparatus may further include an upper encapsulation layer disposed above the second encapsulation layer, and an upper adhesive layer arranged between the upper encapsulation layer and the second encapsulation layer.

In an embodiment, a modulus of the upper encapsulation layer may be less than a modulus of the first encapsulation layer.

In an embodiment, the display apparatus may further include a plurality of dummy-encapsulation layers arranged in the plurality of bridge portions, and the plurality of dummy-encapsulation layers may include a material the same as a material of the first encapsulation layer.

In an embodiment, the plurality of dummy-encapsulation layers may be arranged to correspond to centers of the plurality of bridge portions and may be arranged to be spaced apart from the plurality of first encapsulation layers.

In an embodiment, the plurality of dummy-encapsulation layers may be integrally provided with the plurality of first encapsulation layers.

In an embodiment, the plurality of dummy-encapsulation layers may include reflectors or scattering particles.

In an embodiment, the plurality of first encapsulation layers may include a material that emits a red color, a green color, or a blue color, and the plurality of dummy-encapsulation layers may include a light-blocking material.

In an embodiment, a planar area of each of the plurality of first encapsulation layers may be smaller than an area of each of the plurality of island portions.

In an embodiment, at least one of the lower adhesive layer and the lower encapsulation layer may include a light-blocking material.

In an embodiment, the second encapsulation layer may include a plurality of light-blocking regions including a light-blocking material and disposed in areas corresponding to the plurality of openings.

In an embodiment, the plurality of light-blocking regions may be disposed in areas corresponding to the plurality of bridge portions.

In an embodiment, the at least one light-emitting element may be an organic light-emitting diode including an organic material, and each of the plurality of first encapsulation layers may include a stack of a first inorganic encapsulation layer, an organic encapsulation layer, and a second inorganic encapsulation layer.

In an embodiment, a planar area of the organic encapsulation layer may be smaller than an area of each of the plurality of island portions.

In an embodiment, the at least one light-emitting element may be an inorganic light-emitting diode including an inorganic material, and the first encapsulation layer may not include an inorganic material.

According to one or more embodiments, a display apparatus includes a substrate including a plurality of island portions spaced apart from each other, a plurality of bridge portions connecting the plurality of island portions to each other, a plurality of openings disposed between the plurality of island portions, at least one light-emitting element arranged in each of the plurality of island portions, a plurality of first encapsulation layers disposed on the plurality of island portions, respectively, each of the plurality of first encapsulation layers sealing the at least one light-emitting element, a second encapsulation layer disposed on the plurality of encapsulating layers to cover the plurality of island portions and the plurality of bridge portions, and filling at least upper portions of the plurality of openings, a lower encapsulation layer disposed under the substrate, and a lower adhesive layer arranged between the lower encapsulation layer and the substrate, wherein a planar area of each of the plurality of first encapsulation layers is smaller than a planar area of each of the plurality of island portions.

In an embodiment, a modulus of the second encapsulation layer and a modulus of the lower encapsulation layer may each be less than a modulus of the first encapsulation layer.

In an embodiment, the display apparatus may further include an upper encapsulation layer disposed above the second encapsulation layer, and an upper adhesive layer arranged between the upper encapsulation layer and the second encapsulation layer.

In an embodiment, the display apparatus may further include a plurality of dummy-encapsulation layers arranged in the plurality of bridge portions, and the plurality of dummy-encapsulation layers may include a material the same as a material of the plurality of first encapsulation layers.

In an embodiment, the plurality of first encapsulation layers may include a material that emits a red color, a green color, or a blue color, and the plurality of dummy-encapsulation layers may include a light-blocking material.

In an embodiment, at least one of the lower adhesive layer and the lower encapsulation layer may include a light-blocking material.

In an embodiment, the second encapsulation layer may include a plurality of light-blocking regions which include a light-blocking material.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIGS. 2A and 2B are perspective views showing a state in which the display apparatus of FIG. 1 is stretched in a first direction;

FIG. 2C is a perspective view showing a state in which the display apparatus of FIG. 1 is stretched in a second direction;

FIG. 2D is a perspective view showing a state in which the display apparatus of FIG. 1 is stretched in the first direction and the second direction;

FIG. 2E is a perspective view showing a state in which the display apparatus of FIG. 1 is stretched in a third direction;

FIG. 3 is a schematic plan view of a display apparatus according to an embodiment;

FIG. 4A is an enlarged plan view of portion IV of the display apparatus of FIG. 3 according to an embodiment;

FIG. 4B is an enlarged plan view of portion IV of the display apparatus of FIG. 3 according to an embodiment;

FIG. 4C is an enlarged plan view of portion IV of the display apparatus of FIG. 3 according to an embodiment;

FIG. 5 is a schematic cross-sectional view of a first island portion and a first bridge portion arranged in a display region of a display apparatus according to an embodiment;

FIGS. 6A, 6B and 6C are each equivalent circuit diagram of a sub-pixel of a display apparatus according to an embodiment;

FIGS. 7A and 7B are each a schematic cross-sectional view of a light-emitting element of a display apparatus according to an embodiment;

FIG. 8 is a schematic cross-sectional view of a display apparatus according to an embodiment;

FIGS. 9A, 9B, 9C, 9D, 9E and 9F are schematic diagrams showing a method of manufacturing the display apparatus of FIG. 8;

FIG. 10 is a schematic cross-sectional view of a display apparatus according to an embodiment;

FIG. 11 is a schematic cross-sectional view of a display apparatus according to an embodiment;

FIG. 12 is a schematic plan view of a display apparatus according to an embodiment;

FIG. 13 is a schematic plan view of a display apparatus according to an embodiment;

FIG. 14 is a schematic plan view of a display apparatus according to an embodiment;

FIG. 15 is a schematic plan view of a display apparatus according to an embodiment;

FIG. 16 is a schematic plan view of a display apparatus according to an embodiment;

FIG. 17 is a schematic cross-sectional view of a display apparatus according to an embodiment;

FIG. 18 is a schematic cross-sectional view of a display apparatus according to an embodiment;

FIG. 19 is a schematic cross-sectional view of a display apparatus according to an embodiment;

FIGS. 20 and 21 are each a schematic cross-sectional view of a first encapsulation layer which encapsulates a light-emitting element of a display apparatus, according to an embodiment;

and

FIGS. 22A, 22B, 22C, 22D, 22E, 22F and 22G are each a schematic perspective view of embodiments of an electronic device including a display apparatus, according to an embodiment.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described in detail with reference to the accompanying drawings, and in the description with reference to the drawings, the same or corresponding elements are indicated by the same reference numerals and redundant descriptions thereof are omitted.

In the following embodiment, it will be understood that although the terms “first,” “second,” etc. may be used herein to describe various elements, these elements should not be limited by these terms. These terms are only used to distinguish one element from another.

In the following embodiment, the expression of singularity in the present specification includes the expression of plurality unless clearly specified otherwise in context.

In the following embodiment, it will be further understood that the terms “comprises” and/or “comprising” used herein specify the presence of stated features or elements, but do not preclude the presence or addition of one or more other features or elements.

In the following embodiment, it will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the present specification, the expression “A and/or B” represents A, B, or A and B. In addition, the expression “at least one of A or B” represents A, B, or A and B.

In the following embodiment, it will be understood that when a layer, region, or element is connected to another layer, region, or element, the layers, regions or elements may be directly connected, or/and may also be indirectly connected via another layer, region, or element therebetween. For example, in the present specification, when a layer, region, or element is electrically connected to another layer, region, or element, the layers, regions, or elements may not only be directly electrically connected, but may also be indirectly electrically connected via another layer, region, or element therebetween.

The x-axis, the y-axis, and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

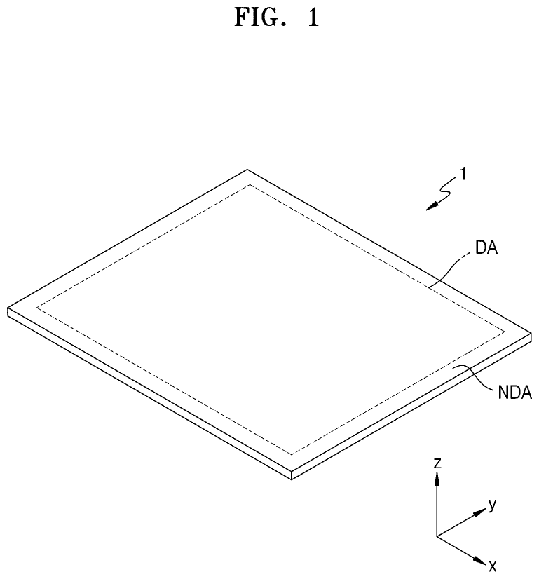

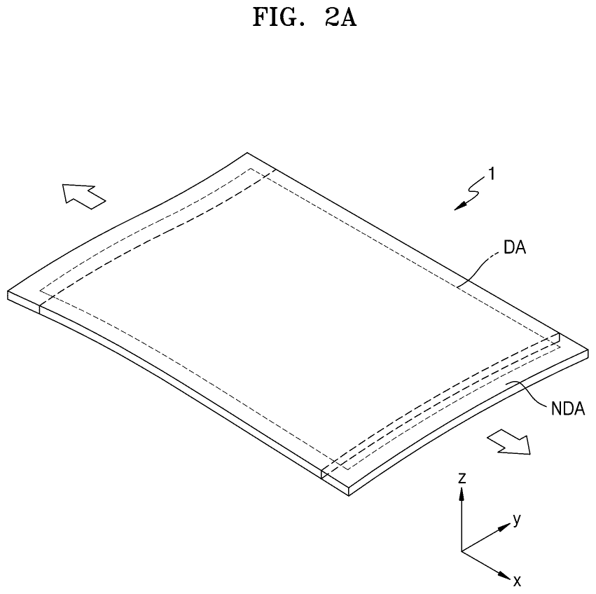

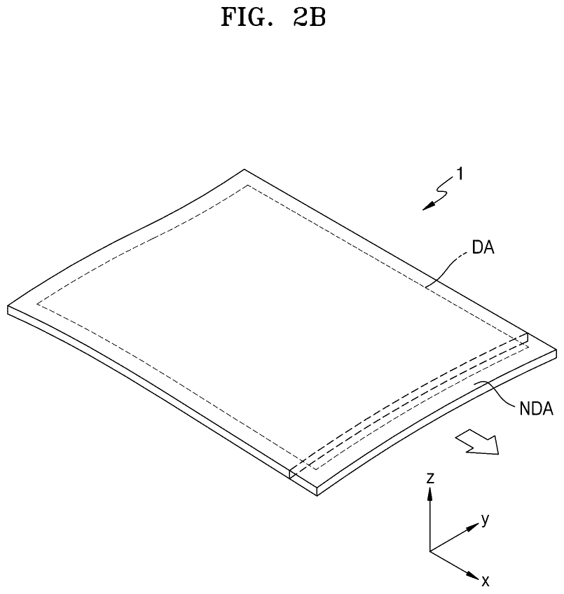

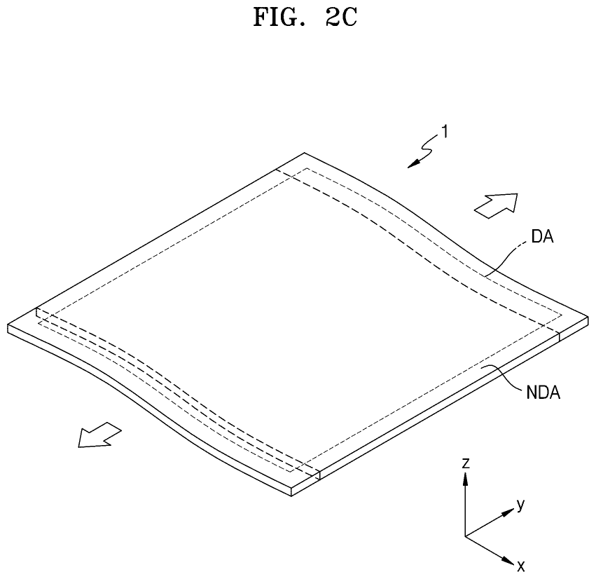

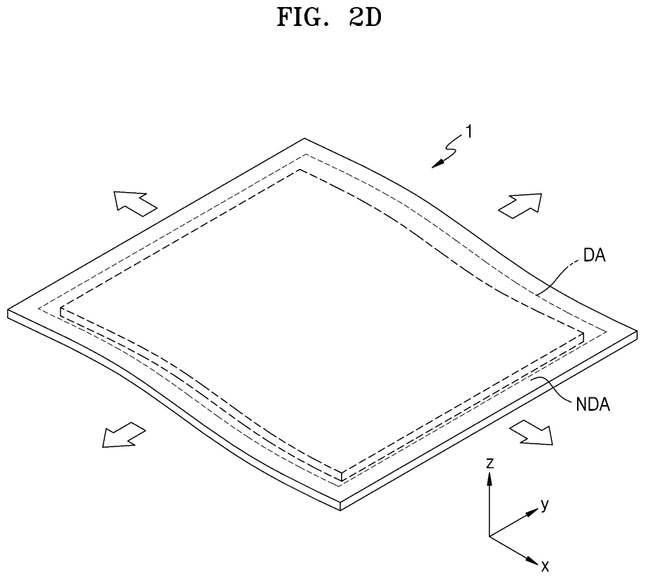

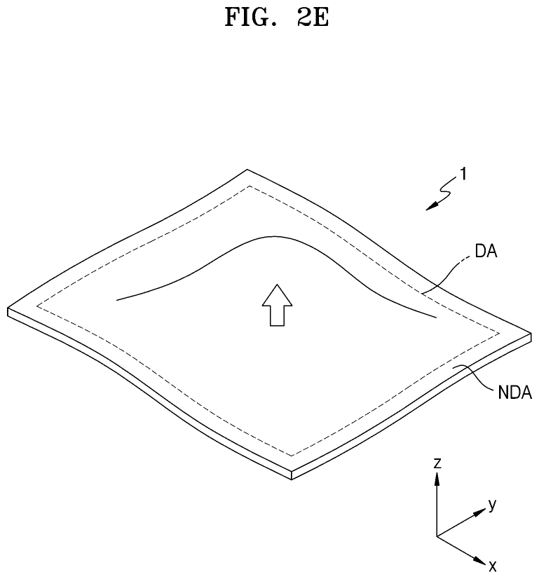

FIG. 1 is a schematic perspective view of a stretchable display apparatus 1 according to an embodiment; FIGS. 2A and 2B are perspective views showing a state in which the stretchable display apparatus 1 of FIG. 1 is stretched in a first direction. FIG. 2C is a perspective view showing a state in which the stretchable display apparatus 1 of FIG. 1 is stretched in a second direction. FIG. 2D is a perspective view showing a state in which the stretchable display apparatus 1 of FIG. 1 is stretched in the first direction and the second direction. FIG. 2E is a perspective view showing a state in which the stretchable display apparatus 1 of FIG. 1 is stretched in a third direction.

Referring to FIG. 1, the stretchable display apparatus 1 may include a display region DA and a non-display region NDA. The display region DA may include a plurality of pixels. The stretchable display apparatus 1 may provide a certain image by using light emitted from the plurality of pixels. The non-display region NDA may be arranged outside the display region DA. The non-display region NDA may completely surround the display region DA.

The stretchable display apparatus 1 may be stretched or shrunk in various directions. The stretchable display apparatus 1 may be stretched in a first direction (for example, x direction and/or −x direction) by an external force applied by an external object or a user. In an embodiment, as shown in FIGS. 2A and 2B, the display region DA and/or the non-display region NDA of the stretchable display apparatus 1 may be stretched in a first direction (for example, x direction and/or −x direction). For example, as shown in FIG. 2A, the stretchable display apparatus 1 may be stretched in the x direction and −x direction, or as shown in FIG. 2B, the stretchable display apparatus 1 may be stretched in the x direction while one side of the stretchable display apparatus 1 is fixed.

The stretchable display apparatus 1 may be stretched in a second direction (for example, y direction and/or −y direction) by an external force applied by an external object or a user. In an embodiment, as shown in FIG. 2C, the display region DA and/or the non-display region NDA of the stretchable display apparatus 1 may be stretched in the y direction and −y direction. In some embodiments, the stretchable display apparatus 1 may be stretched in the y direction or −y direction while one side of the stretchable display apparatus 1 is fixed.

The stretchable display apparatus 1 may be stretched in a plurality of directions, for example, a first direction (for example, x direction and/or −x direction) and a second direction (for example, y direction and/or −y direction), by an external force applied by an external object or a part of a human body. As shown in FIG. 2D, the display region DA and/or the non-display region NDA of the stretchable display apparatus 1 may be stretched in the +x direction and the ty direction.

The stretchable display apparatus 1 may be stretched in a third direction (for example, z direction or −z direction) by an external force applied by an external object or a part of a human body. In an embodiment, FIG. 2E illustrates that a portion of the stretchable display apparatus 1, for example, a partial region of the display region DA, protrudes in the z direction. In some embodiments, a portion of the stretchable display apparatus 1, for example, a partial region of the display region DA, may protrude in the −z direction (or may be recessed in the z direction).

FIGS. 2A to 2E illustrate that the stretchable display apparatus 1 is stretched in the first direction, the second direction, and/or the third direction, but the disclosure is not limited thereto. In some embodiments, the stretchable display apparatus 1 may be transformed into various atypical shapes such as by being bent or twisted along two or more axes.

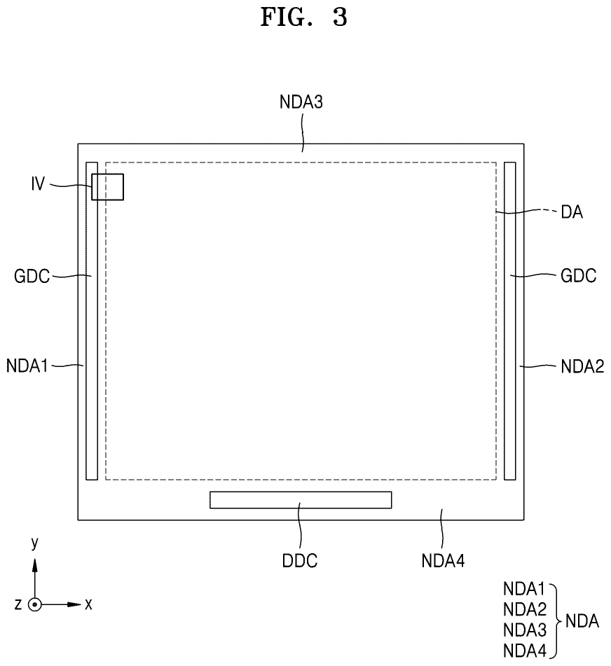

FIG. 3 is a schematic plan view of the stretchable display apparatus 1 according to an embodiment.

A plurality of pixels may be arranged in the display region DA of the stretchable display apparatus 1. Each pixel may include sub-pixels which emit light of different colors from each other. A light-emitting element corresponding to each sub-pixel may be arranged in the display region DA. A circuit for providing an electrical signal to light-emitting elements arranged in the display region DA and transistors electrically connected to the light-emitting elements may be arranged in the non-display region NDA surrounding the display region DA. A gate driving circuit GDC may be arranged in each of a first non-display region NDA1 and a second non-display region NDA2 arranged on both sides of the display region DA. The gate driving circuit GDC may include drivers for providing an electrical signal to a gate electrode of each of the transistors electrically connected to the light-emitting elements. FIG. 3 illustrates that the gate driving circuit GDC is arranged in each of the first non-display region NDA1 and the second non-display region NDA2, but the disclosure is not limited thereto. In some embodiments, the gate driving circuit GDC may be arranged in one of the first non-display region NDA1 and the second non-display region NDA2.

A data driving circuit DDC may be arranged in a third non-display region NDA3 and/or a fourth non-display region NDA4 connecting the first non-display region NDA1 and the second non-display region NDA2. In an embodiment, FIG. 3 illustrates that the data driving circuit DDC is arranged in the fourth non-display region NDA4. In some embodiments, the data driving circuit DDC may be arranged in each of the third non-display region NDA3 and the fourth non-display region NDA4.

FIG. 3 illustrates that the data driving circuit DDC is arranged in the fourth non-display region NDA4 of the stretchable display apparatus 1, but the disclosure is not limited thereto. In some embodiments, the stretchable display apparatus 1 may further include a flexible circuit substrate (not shown) electrically connected to the stretchable display apparatus 1 via a terminal portion (not shown) arranged in the fourth non-display region NDA4, and the data driving circuit DDC may be disposed on the flexible circuit substrate.

In some embodiments, the elongation rate of the non-display region NDA may be less than or equal to the elongation rate of the display region DA. In an embodiment, the elongation rate of the non-display region NDA may vary by region. For example, the first non-display region NDA1, the second non-display region NDA2, and the third non-display region NDA3 may have substantially the same elongation rate, but the elongation rate of the fourth non-display region NDA4 may be less than the elongation rate of each of the first non-display region NDA1, the second non-display region NDA2, and the third non-display region NDA3.

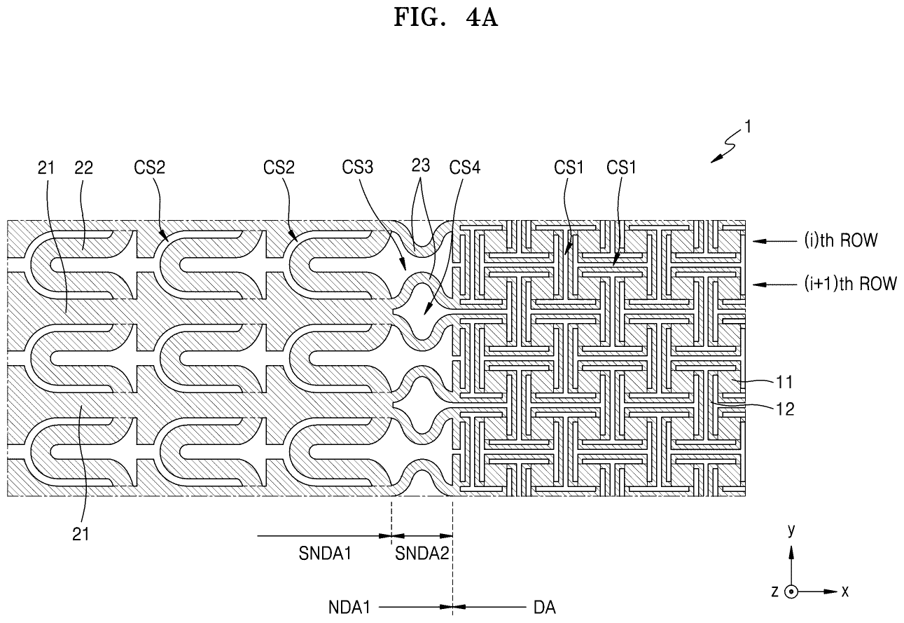

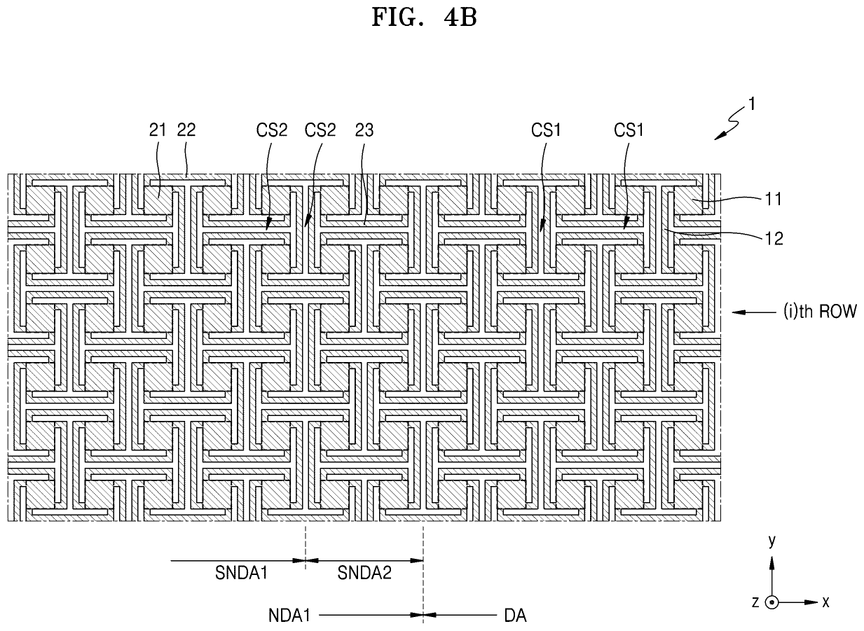

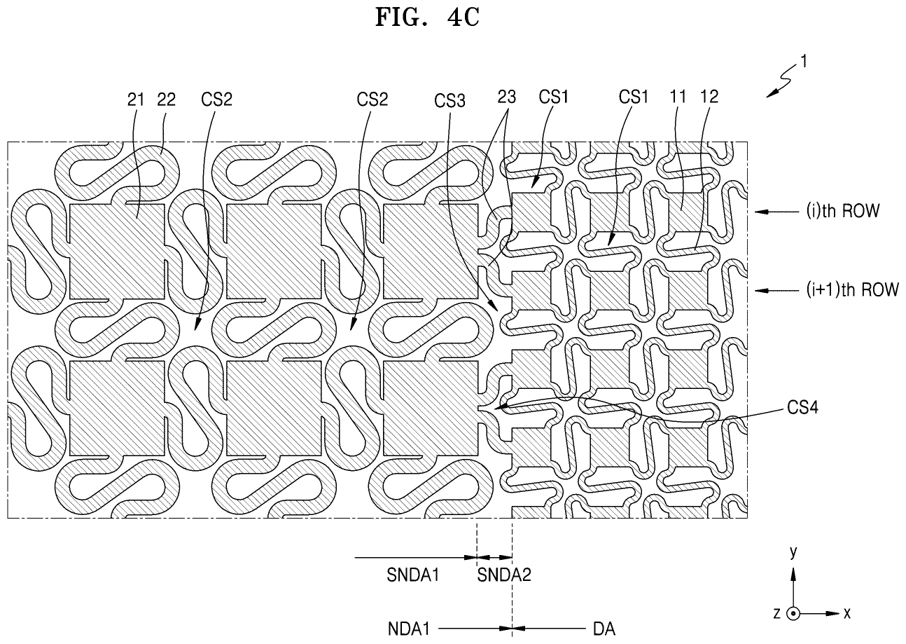

FIG. 4A is an enlarged plan view of portion IV of the stretchable display apparatus 1 of FIG. 3, according to an embodiment.

Referring to FIG. 4A, the stretchable display apparatus 1 may include first island portions 11 spaced apart from each other in a first direction (for example, x direction or −x direction) and a second direction (for example, y direction or −y direction), and first bridge portions 12 connecting neighboring first island portions 11 to each other in the display region DA.

Each first island portion 11 may be connected to a plurality of first bridge portions 12. For example, each first island portion 11 may be connected to four first bridge portions 12. Two first bridge portions 12 may be arranged on both sides of the first island portion 11 in a first direction (for example, x direction or −x direction), and the remaining two first bridge portions 12 may be arranged on both sides of the first island portion 11 in a second direction (for example, y direction or −y direction). In an embodiment, four first bridge portions 12 may be respectively connected to four sides of the first island portion 11. Each of the four first bridge portions 12 may be connected to an area disposed adjacent to each corner of the first island portion 11.

The first bridge portions 12 may be spaced apart from each other by a first opening CS1 arranged between the first bridge portions 12. In an embodiment, the first opening CS1 having an approximately H shape and the first opening CS1 having an approximately I shape obtained by rotating the H shape by 90 degrees may be alternately and repeatedly arranged in a first direction (for example, x direction or −x direction) and a second direction (for example, y direction or −y direction). Both end portions of each first bridge portion 12 may be respectively connected to neighboring first island portions 11, and one side of each first bridge portion 12 may be spaced apart from one side of a neighboring first island portion 11 and/or one side of another first bridge portion 12 by the first opening CS1.

The stretchable display apparatus 1 may include second island portions 21 spaced apart from each other and second bridge portions 22 connecting neighboring second island portions 21 to each other in a non-display region, for example, the first non-display region NDA1 shown in FIG. 4A.

Each second island portion 21 may extend in a first direction (for example, x direction or −x direction). The second island portions 21 may be spaced apart from each other in a second direction (for example, y direction or −y direction) crossing the first direction (for example, x direction or −x direction). Each second island portion 21 may include drivers of the gate driving circuit GDC (FIG. 2) described with reference to FIG. 3.

The second bridge portion 22 may have a serpentine shape. The length of the second bridge portion 22 may be greater than the shortest distance between neighboring second island portions 21 in a second direction (for example, y direction or −y direction). In an embodiment, the second bridge portion 22 may have an approximately omega (Ω) shape that is convex in a first direction (for example, x direction or −x direction). The second bridge portions 22 may be arranged between neighboring second island portions 21 and may be spaced apart from each other.

The second bridge portions 22 between neighboring second island portions 21 may be spaced apart from each other by a second opening CS2. The second openings CS2 and the second bridge portions 22 may be alternately arranged between neighboring second island portions 21 in a first direction (for example, x direction or −x direction). The second openings CS2 may have the same shape. Both end portions of each second bridge portion 22 may be connected to neighboring second island portions 21, and one side of each second bridge portion 22 may be spaced apart from one side of a neighboring second island portion 21 and/or another second bridge portion 22 by the second opening CS2.

One second island portions 21 arranged in the first non-display region NDA1 may have a length corresponding to the first island portions 11 in a plurality of rows arranged in the display region DA. For example, one second island portion 21 arranged in the first non-display region NDA1 may have the length corresponding to the first island portions 11 arranged in an i^{th} row and the first island portions 11 arranged in an (i+1)^{th} row in the display region DA (in this regard, i is a positive number greater than 0). FIG. 4A illustrates that one second island portion 21 has a length corresponding to two rows of the first island portions 11, but the disclosure is not limited thereto. In some embodiments, one second island portion 21 arranged in the first non-display region NDA1 may have the length correspond to n rows of the first island portions 11 arranged in the display region DA (in this regard, n is a positive number greater than or equal to 3).

A non-display region, for example, the first non-display region NDA1, may include a first sub-non-display region SNDA1 in which the second island portions 21 and the second bridge portions 22 are arranged, and a second sub-non-display region SNDA2 disposed between the first sub-non-display region SNDA1 and the display region DA. Third bridge portions 23 may be arranged in the second sub-non-display region SNDA2 to connect the display region DA and the first sub-non-display region SNDA1. One end portion of the third bridge portion 23 may be connected to the second island portion 21 and/or the second bridge portion 22, and the other end portion of the third bridge portion 23 may be connected to the first island portion 11 and/or the first bridge portion 12. For example, the other end portion of the third bridge portion 23 may be connected to first island portions 11 via first bridge portions 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may have an approximately omega (Ω) shape that is convex in a second direction (for example, y direction or −y direction). Neighboring third bridge portions 23 arranged in a second direction (for example, y direction or −y direction) may be symmetrical to each other with a line of symmetry disposed therebetween, wherein one of the neighboring third bridge portions 23 is convex in the y direction, and the other is convex in the −y direction. A third opening CS3 and a fourth opening CS4, which have different shapes from each other, may be alternatingly repeated between the third bridge portions 23. The width of the third bridge portion 23 may be different from the width of the first bridge portion 12 and the width of the second bridge portion 22. In an embodiment, the width of the third bridge portion 23 may be greater than the width of the first bridge portion 12 and may be less than the width of the second bridge portion 22.

FIG. 4A illustrates that the second island portion 21 and the second bridge portion 22 of a non-display region, for example, the first non-display region NDA1, have shapes different from those of the first island portion 11 and the first bridge portion 12 of the display region DA, respectively. In some embodiments, the second island portion 21 and the second bridge portion 22 of a non-display region may have shapes the same as those of the first island portion 11 and the first bridge portion 12 of the display region DA, respectively.

FIG. 4B is an enlarged plan view of portion IV of the stretchable display apparatus 1 of FIG. 3, according to an embodiment.

Referring to FIG. 4B, the stretchable display apparatus 1 includes the first island portions 11 spaced apart from each other and the first bridge portions 12 spaced apart from each other by the first opening CS1 and connecting neighboring first island portions 11 to each other in the display region DA. The structure of the display region DA of FIG. 4B may be the same as the structure of the display region DA described with reference to FIG. 4A.

The stretchable display apparatus 1 may include the second island portions 21 and the second bridge portions 22 arranged in a non-display region, for example, the first non-display region NDA1. In an embodiment, the second island portions 21 and the second bridge portions 22 may have shapes substantially the same as those of the first island portions 11 and the first bridge portions 12, respectively.

The second island portions 21 may be spaced apart from each other in a non-display region, for example, the first non-display region NDA1, in a first direction (for example, x direction or −x direction) and a second direction (for example, y direction or −y direction). Each of the second bridge portions 22 may connect neighboring second island portions 21 to each other. The second bridge portions 22 may be spaced apart from each other by the second opening CS2 arranged between the second bridge portions 22.

The second opening CS2 may have a shape substantially the same as that of the first opening CS1. For example, the second opening CS2 having an approximately H shape and the second opening CS2 having an approximately I shape may be alternately and repeatedly arranged in a non-display region, for example, the first non-display region NDA1. Both end portions of each second bridge portion 22 may be respectively connected to neighboring second island portions 21, and one side of each second bridge portion 22 may be spaced apart from one side of a neighboring second island portion 21 and/or one side of another second bridge portion 22 by the second opening CS2.

Each second island portion 21 may be connected to four second bridge portions 22. Each second island portion 21 may include drivers of the gate driving circuit GDC (FIG. 2) described with reference to FIG. 3.

The second island portions 21 in one row arranged in the first non-display region NDA1 may have a length corresponding to the first island portions 11 in one row arranged in the display region DA. For example, the second island portions 21 arranged in an i^{th} row in a first direction (for example, x direction or −x direction) in the first non-display region NDA1 may have the length corresponding to the first island portions 11 arranged in the same row, for example, the i^{th} row, in the display region DA (in this regard, i is a positive number greater than 0).

The stretchable display apparatus 1 may include the third bridge portions 23 arranged in the second sub-non-display region SNDA2 for connecting the display region DA to the first sub-non-display region SNDA1. A non-display region, for example, the first non-display region NDA1 may include the first sub-non-display region SNDA1 in which the second island portions 21 and the second bridge portions 22 are arranged, and the second sub-non-display region SNDA2 including the third bridge portions 23 and arranged between the first sub-non-display region SNDA1 and the display region DA. The third bridge portion 23 may be substantially the same as the first bridge portion 12 and the second bridge portion 22. For example, the width of the third bridge portion 23 may be the same as the width of the first bridge portion 12 and the width of the second bridge portion 22.

FIG. 4C is an enlarged plan view of portion IV of the stretchable display apparatus 1 of FIG. 3 according to an embodiment.

Referring to FIG. 4C, the stretchable display apparatus 1 may include the first island portions 11 spaced apart from each other in a first direction (for example, x direction or −x direction) and a second direction (for example, y direction or −y direction), and the first bridge portions 12 connecting neighboring first island portions 11 to each other in the display region DA.

The first bridge portions 12 may be arranged spaced apart from each other by the first opening CS1 arranged between the first bridge portions 12. The first bridge portion 12 may have a serpentine shape. For example, as shown in FIG. 4C, the first bridge portion 12 may have an approximate S shape.

Each first island portion 11 may be connected to a plurality of first bridge portions 12. For example, each first island portion 11 may be connected to four first bridge portions 12. Two first bridge portions 12 may be arranged on both sides of the first island portion 11 in a first direction (for example, x direction or −x direction), and the remaining two first bridge portions 12 may be arranged on both sides of the first island portion 11 in a second direction (for example, y direction or −y direction). Four first bridge portions 12 may be respectively connected to four sides of the first island portion 11. Each of the four first bridge portions 12 may be connected to an area disposed adjacent to each corner of the first island portion 11.

The stretchable display apparatus 1 may include second island portions 21 spaced apart from each other in a first direction (for example, x direction or −x direction) and a second direction (for example, y direction or −y direction), and the second bridge portions 22 connecting neighboring second island portions 21 to each other in a non-display region, for example, in the first non-display region NDA1 shown in FIG. 4C.

The second bridge portions 22 may be arranged spaced apart from each other by the second opening CS2 arranged between the second bridge portions 22. The second bridge portion 22 may have a serpentine shape. For example, as shown in FIG. 4C, the second bridge portion 22 may have an approximate S shape. The size and/or width of the second bridge portion 22 may be different from the size and/or width of the first bridge portion 12. For example, the size and/or width of the second bridge portion 22 may be greater than the size and/or width of the first bridge portion 12. The radius of curvature of a rounded portion of the second bridge portion 22 may be different from the radius of curvature of a rounded portion of the first bridge portion 12. For example, the radius of curvature of a rounded portion of the second bridge portion 22 may be greater than the radius of curvature of a rounded portion of the first bridge portion 12.

Each second island portion 21 may be connected to a plurality of second bridge portions 22. Each second island portion 21 may be connected to four second bridge portions 22. Two second bridge portions 22 may be arranged on both sides of the second island portion 21 in a first direction (for example, x direction or −x direction), and the remaining two second bridge portions 22 may be arranged on both sides of the second island portion 21 in a second direction (for example, y direction or −y direction). In an embodiment, four second bridge portions 22 may be respectively connected to four sides of the second island portion 21. Each second bridge portion 22 may be connected to a central portion of each side of the second island portion 21.

The second island portions 21 in one row arranged in the first non-display region NDA1 may have a length corresponding to the first island portions 11 in a plurality of rows arranged in the display region DA. For example, the second island portions 21 in one row arranged in the first non-display region NDA1 may have a length corresponding to the first island portions 11 arranged in an i^{th} row of the display region DA and the first island portions 11 arranged in an (i+1)th row (in this regard, i is a positive number greater than 0). In some embodiments, the second island portions 21 in one row may have a length corresponding to n rows of the first island portions 11 (in this regard, n is a positive number greater than or equal to 3).

A non-display region, for example, the first non-display region NDA1, may include the first sub-non-display region SNDA1 in which the second island portions 21 and the second bridge portions 22 are arranged, and the second sub-non-display region SNDA2 disposed between the first sub-non-display region SNDA1 and the display region DA. The third bridge portions 23 may be arranged in the second sub-non-display region SNDA2 to connect the display region DA and the first sub-non-display region SNDA1. One end portion of the third bridge portion 23 may be connected to the second island portion 21, and the other end portion of the third bridge portion 23 may be connected to the first island portion 11. For example, one end portion of the third bridge portion 23 may be connected to a central portion of one side of the second island portion 21, and the other end portion of the third bridge portion 23 may be connected to a central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and may be less than the width of the second bridge portion 22. The third opening CS3 and the fourth opening CS4, which have different shapes from each other, may be alternately arranged between the third bridge portions 23 in a second direction (for example, y direction or −y direction).

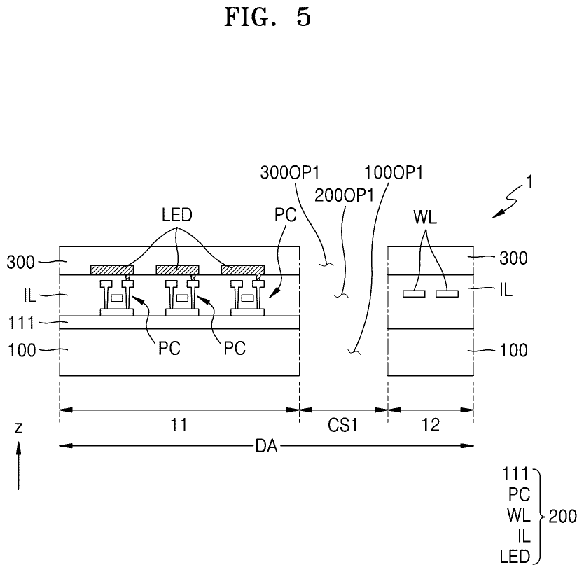

FIG. 5 is a schematic cross-sectional view of the first island portion 11 and the first bridge portion 12 arranged in the display region DA of the stretchable display apparatus 1, according to an embodiment.

Referring to FIG. 5, the first island portion 11 and the first bridge portion 12 arranged in the display region DA may be spaced apart from each other with the first opening CS1 disposed therebetween. The first island portion 11 may include light-emitting elements LED and a circuit, for example, a pixel driving circuit PC, which is electrically connected to the light-emitting elements LED and is configured to drive the light-emitting elements LED, and the first bridge portion 12 may include a wire WL electrically connected to the pixel driving circuits PC arranged in each of first island portions 11 disposed adjacent to the first bridge portion 12.

In the first island portion 11, a buffer layer 111 including an inorganic insulating material may be disposed on a substrate 100 and the pixel driving circuit PC may be disposed on the buffer layer 111. An insulating layer IL including an inorganic insulating material and/or an organic insulating material may be arranged between the pixel driving circuit PC and the light-emitting element LED. The light-emitting element LED may be disposed on the insulating layer IL and may be electrically connected to a corresponding pixel driving circuit PC. The light-emitting elements LED may emit light of different colors or may emit light of the same color. In an embodiment, the light-emitting elements LED may respectively emit red light, green light, and blue light. In some embodiments, the light-emitting elements LED may emit white light. In some embodiments, the light-emitting elements LED may respectively emit red light, green light, blue light, and white light.

The substrate 100 may include a polymer resin such as polyethersulfone, polyarylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may be a single layer including the polymer resin. In some embodiments, the substrate 100 may have a multilayer structure including a base layer including the polymer resin and a barrier layer including an inorganic insulating material. The substrate 100 including a polymer resin may be flexible, rollable, and bendable.

In an embodiment, FIG. 5 illustrates that three pixel driving circuits PC are arranged in each first island portion 11 and illustrates three light-emitting elements LED respectively connected to the pixel driving circuits PC, but the disclosure is not limited thereto. In some embodiments, the number of pixel driving circuits PC arranged in the first island portion 11 and the number of the light-emitting elements LED arranged in the first island portion 11 may each be one, two, or four or more.

A first encapsulation layer 300 may be disposed on the light-emitting element LED and may protect the light-emitting element LED from an external force or moisture permeation. The first encapsulation layer 300 may include an inorganic encapsulation layer and/or an organic encapsulation layer. In some embodiments, the first encapsulation layer 300 may include a structure in which an inorganic encapsulation layer including an inorganic insulating material, an organic encapsulation layer including an organic insulating material, and an inorganic encapsulation layer including an inorganic insulating material are stacked. In some embodiments, the first encapsulation layer 300 may include an organic material such as resin. In some embodiments, the first encapsulation layer 300 may include urethane epoxy acrylate. The first encapsulation layer 300 may include a photosensitive material, for example, a material such as photoresist.

In the first bridge portion 12, the insulating layer IL including an organic insulating material may be disposed on the substrate 100. Unlike the first island portion 11, the first bridge portion 12, which is relatively highly deformed when the stretchable display apparatus 1 is stretched, does not have a layer including an inorganic insulating material that is prone to cracks.

In an embodiment, the substrate 100 corresponding to the first bridge portion 12 may have a stacked structure the same as that of the substrate 100 corresponding to the first island portion 11. In an embodiment, the substrate 100 corresponding to the first bridge portion 12 and the substrate 100 corresponding to the first island portion 11 may be polymer resin layers formed together in the same process. In some embodiments, the substrate 100 corresponding to the first bridge portion 12 may have a stacked structure different from that of the substrate 100 corresponding to the first island portion 11. In some embodiments, the substrate 100 corresponding to the first bridge portion 12 may have a multilayer structure including a base layer including a polymer resin and a barrier layer including an inorganic insulating material, and the substrate 100 corresponding to the first bridge portion 12 may have a structure of a polymer resin layer without a layer including an inorganic insulating material.

The wires WL in the first bridge portion 12 may be a signal line (for example, a gate line, a data line, etc.) for providing an electrical signal to a transistor included in the pixel driving circuit PC of the first island portion 11, or a voltage line (for example, a driving voltage line, an initialization voltage line, etc.) for providing a voltage to a transistor included in the pixel driving circuit PC of the first island portion 11. The first encapsulation layer 300 may also be arranged in the first bridge portion 12. In some embodiments, the first encapsulation layer 300 may not exist in the first bridge portion 12.

Referring to FIGS. 4A to 4C and 5, the substrate 100 corresponding to the first island portion 11 and the substrate 100 corresponding to the first bridge portion 12 may be connected to each other. In other words, the plan views shown in FIGS. 4A to 4C may be substantially the same as a plan view of the substrate 100 of FIG. 5. In other words, the substrate 100 may include a region corresponding to the first island portion 11, a region corresponding to the first bridge portion 12, and an opening 100OP1 having a shape the same as that of the first opening CS1.

Similarly, the first encapsulation layer 300 corresponding to the first island portion 11 and the first encapsulation layer 300 corresponding to the first bridge portion 12 may be connected to each other. For example, the plan views shown in FIGS. 4A to 4C may be substantially the same as a plan view of the first encapsulation layer 300. In other words, the first encapsulation layer 300 may include a region corresponding to the first island portion 11, a region corresponding to the first bridge portion 12, and an opening 300OP1 having a shape the same as that of the first opening CS1.

A circuit-light-emitting element layer 200 disposed between the substrate 100 and the first encapsulation layer 300 may include the buffer layer 111, the pixel driving circuit PC, the wire WL, the insulating layer IL, and the light-emitting element LED. Similar to the substrate 100, the plan views shown in FIGS. 4A to 4C may be substantially the same as a plan view of the circuit-light-emitting element layer 200. In other words, the circuit-light-emitting element layer 200 may include an opening 200OP1 having a shape the same as that of the first opening CS1.

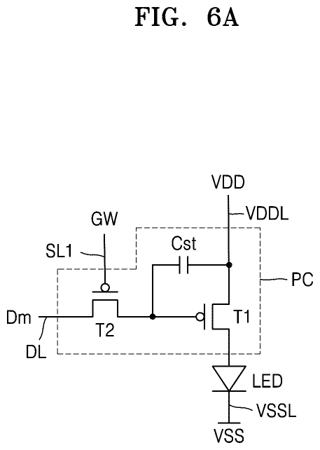

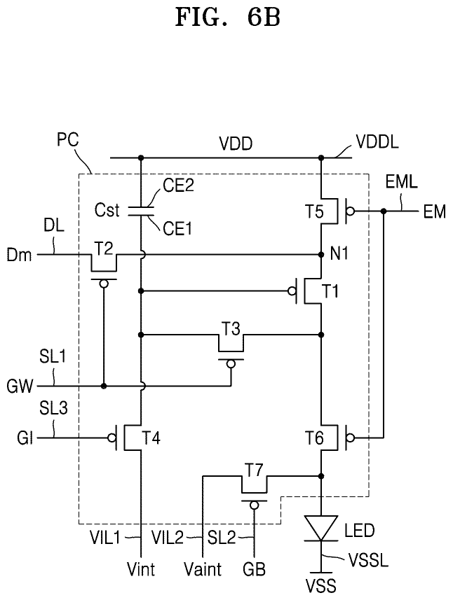

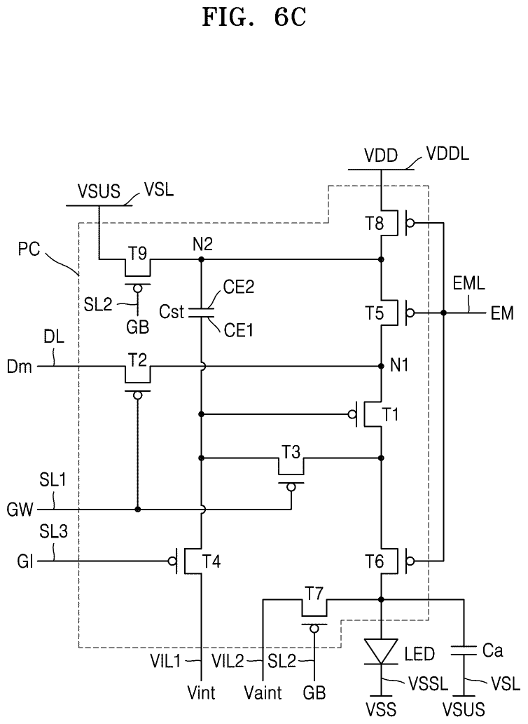

FIGS. 6A to 6C are each equivalent circuit diagram of a sub-pixel of the stretchable display apparatus 1 according to an embodiment.

Referring to FIG. 6A, the light-emitting element LED corresponding to a sub-pixel may be electrically connected to the pixel driving circuit PC, and the pixel driving circuit PC may include a first transistor T1, a second transistor T2, and a storage capacitor Cst. The pixel driving circuit PC may be electrically connected to signal lines and voltage lines. The signal line may include a gate line, such as a first scan line SL1, and a data line DL, and the voltage line may include a first voltage line VDDL and a second power voltage line VSSL.

The second transistor T2 may be electrically connected to the first scan line SL1 and the data line DL. The first scan line SL1 may be configured to provide a first scan signal GW1 to a gate electrode of the second transistor T2. The second transistor T2 may be configured to transmit a data signal Dm input from the data line DL to a gate of the first transistor T1 according to the first scan signal GW1 input from the first scan line SL1.

The storage capacitor Cst may be electrically connected between the second transistor T2 and the first voltage line VDDL and may store a voltage corresponding to a difference between a data voltage received from the second transistor T2 and a first power voltage VDD supplied by the first voltage line VDDL.

The first transistor T1 may be a driving transistor and may be configured to control a driving current flowing through the light-emitting element LED. The first transistor T1 may be connected between the first voltage line VDDL and the light-emitting element LED. The first transistor T1 may be configured to control a driving current flowing from the first voltage line VDDL to the light-emitting element LED according to a voltage value stored in the storage capacitor Cst. The light-emitting element LED may emit light having a certain luminance according to the driving current. A first electrode of the light-emitting element LED may be electrically connected to the first transistor T1, and a second electrode thereof may be electrically connected to a second voltage line VSSL configured to supply a second power voltage VSS.

FIG. 6A illustrates that the pixel driving circuit PC includes two transistors and one storage capacitor, but, in some embodiments, the pixel driving circuit PC may include at least three transistors.

Referring to FIG. 6B, the pixel driving circuit PC may include a first transistor T1, a second transistor T2, a third transistor T3, a fourth transistor T4, a fifth transistor T5, a sixth transistor T6, a seventh transistor T7, and the storage capacitor Cst.

The pixel driving circuit PC may be electrically connected to signal lines and voltage lines. The signal lines may include a gate line, such as the first scan line SL1, a second scan line SL2, a third scan line SL3, a fourth scan line SLA, and an emission control line EML, and the data line DL. The voltage lines may include first and second initialization voltage lines VIL1 and VIL2, a first voltage line VDDL and a second voltage line VSSL.

The first voltage line VDDL may be configured to transmit the first power voltage VDD to the first transistor T1. The first initialization voltage line VIL1 may be configured to transmit, a first initialization voltage Vint that initializes the first transistor T1 to the pixel driving circuit PC. The second initialization voltage line VIL2 may be configured to transmit a second initialization voltage Vaint that initializes the first electrode of the light-emitting element LED to the pixel driving circuit PC. The second voltage line VSSL may be configured to transmit the second power voltage VSS to the light-emitting element LED.

The first transistor T1 may be electrically connected to the first voltage line VDDL via the fifth transistor T5 and may be electrically connected to the light-emitting element LED via the sixth transistor T6. The first transistor T1 acts as a driving transistor and is configured to receive the data signal Dm according to a switching operation of the second transistor T2 and supply a driving current to the light-emitting element LED.

The second transistor T2 is a data write transistor and is electrically connected to the first scan line SL1 and the data line DL. The second transistor T2 is electrically connected to the first voltage line VDDL via the fifth transistor T5. The second transistor T2 is configured to be turned on in response to a first scan signal GW received via the first scan line SL1 to perform a switching operation of transmitting the data signal Dm transmitted from the data line DL to a first node N1.

The third transistor T3 is electrically connected to the first scan line SL1 and is electrically connected to the light-emitting element LED via the sixth transistor T6. The third transistor T3 may be configured to be turned on in response to the first scan signal GW received via the first scan line SL1 to diode-connect the first transistor T1.

The fourth transistor T4 is a first initialization transistor and is electrically connected to the third scan line SL3 and the first initialization voltage line VIL1. The fourth transistor T4 is configured to turned on in response to a third scan signal GI received via the third scan line SL3 to transmit the first initialization voltage Vint from the first initialization voltage line VIL1 to the gate electrode of the first transistor T1 and initialize a voltage of the gate electrode of the first transistor T1. The third scan signal GI may correspond to a first scan signal of another pixel driving circuit arranged in a previous row of the corresponding pixel driving circuit PC.

The fifth transistor T5 may be an operation control transistor, and the sixth transistor T6 may be an emission control transistor. The fifth transistor T5 and the sixth transistor T6 are electrically connected to the emission control line EML, and are configured to be simultaneously turned on in response to an emission control signal EM received via the emission control line EML to form a current path, such that a driving current flows from the first voltage line VDDL to the light-emitting element LED.

The seventh transistor T7 may be a second initialization transistor and may be electrically connected to the second scan line SL2, the second initialization voltage line VIL2, and the sixth transistor T6. The seventh transistor T7 may be configured to be turned on in response to a second scan signal GB received via the second scan line SL2, and may be configured to transmit the second initialization voltage Vaint from the second initialization voltage line VIL2 to the first electrode of the light-emitting element LED and initialize the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may store and maintain a voltage corresponding to a difference in voltage between the first voltage line VDDL and the gate electrode of the first transistor T1 to maintain a voltage applied to the gate electrode of the first transistor T1.

Referring to FIG. 6C, the pixel driving circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, the storage capacitor Cst, and an auxiliary capacitor Ca.

The pixel driving circuit PC is electrically connected to signal lines and voltage lines. The signal lines may include a gate line, such as the first scan line SL1, the second scan line SL2, the third scan line SL3, the fourth scan line SL4, and the emission control line EML, and the data line DL. The voltage lines may include the first and second initialization voltage lines VIL1 and VIL2, a maintenance voltage line VSL, the first voltage line VDDL, and the second voltage line VSSL.

The first voltage line VDDL may be configured to transmit the first power voltage VDD to the first transistor T1. The first initialization voltage line VIL1 may be configured to transmit a first initialization voltage Vint that initializes the first transistor T1 to the pixel driving circuit PC. The second initialization voltage line VIL2 may be configured to transmit the second initialization voltage Vaint that initializes the first electrode of the light-emitting element LED to the pixel driving circuit PC. The maintenance voltage line VSL may be configured to provide a maintenance voltage VSUS to a second node N2, for example, the second electrode CE2 of the storage capacitor Cst during an initialization period and a data write period. The second voltage line VSSL may be configured to transmit a second power voltage VDD to the light-emitting element LED.

The first transistor T1 may be electrically connected to the first voltage line VDDL via the fifth transistor T5 and the eighth transistor T8 and may be electrically connected to the light-emitting element LED via the sixth transistor T6. The first transistor T1 may act as a driving transistor and may be configured to receive the data signal Dm according to a switching operation of the second transistor T2 and supply a driving current to the light-emitting element LED.

The second transistor T2 is electrically connected to the first scan line SL1 and the data line DL and is electrically connected to the first voltage line VDDL via the fifth transistor T5 and the eighth transistor T8. The second transistor T2 is configured to be turned on in response to the first scan signal GW received via the first scan line SL1 to perform a switching operation of transmitting the data signal Dm transmitted from the data line DL to the first node N1.

The third transistor T3 is electrically connected to the first scan line SL1 and is electrically connected to the light-emitting element LED via the sixth transistor T6. The third transistor T3 may be configured to be turned on in response to the first scan signal GW received via the first scan line SL1 to diode-connect the first transistor T1, thereby compensating for a threshold voltage of the first transistor T1.

The fourth transistor T4 is electrically connected to the third scan line SL3 and the first initialization voltage line VIL1, and is configured to be turned on in response to the third scan signal GI received via the third scan line SL3 to transmit the first initialization voltage Vint from the first initialization voltage line VIL1 to the gate electrode of the first transistor T1 and initialize a voltage of the gate electrode of the first transistor T1. The third scan signal GI may correspond to a first scan signal of another pixel driving circuit arranged in a previous row of the corresponding pixel driving circuit PC.

The fifth transistor T5, the sixth transistor T6, and the eighth transistor T8 are electrically connected to the emission control line EML, and are configured to be simultaneously turned on in response to the emission control signal EM received via the emission control line EML to form a current path, such that a driving current flows from the first voltage line VDDL to the light-emitting element LED.

The seventh transistor T7 may be a second initialization transistor and may be electrically connected to the second scan line SL2, the second initialization voltage line VIL2, and the sixth transistor T6. The seventh transistor T7 is configured to be turned on in response to the second scan signal GB received via the second scan line SL2 to transmit the second initialization voltage Vaint from the second initialization voltage line VIL2 to the first electrode of the light-emitting element LED and initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be configured to be turned on in response to the second scan signal GB received via the second scan line SL2, and may be configured to transmit the maintenance voltage VSUS to the second node N2, for example, the second electrode CE2 of the storage capacitor Cst during an initialization period and a data write period.

Each of the eighth transistor T8 and the ninth transistor T9 may be electrically connected to the second node N2, for example, the second electrode CE2 of the storage capacitor Cst. In some embodiments, during an initialization period and a data write period, the eighth transistor T8 may be turned off and the ninth transistor T9 may be turned on, and, during an emission period, the eighth transistor T8 may be turned on and the ninth transistor T9 may be turned off. During the initialization period and the data write period, the second node N2 receives the maintenance voltage VSUS, and thus, the uniformity (for example, long range uniformity (LRU)) of the luminance of the stretchable display apparatus 1 according to a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to a difference in voltage between the first electrode of the light-emitting element LED and the maintenance voltage line VSL while the seventh transistor T7 and the ninth transistor T9 are turned on, thereby preventing a problem of black luminance increasing when the sixth transistor T6 is turned off.

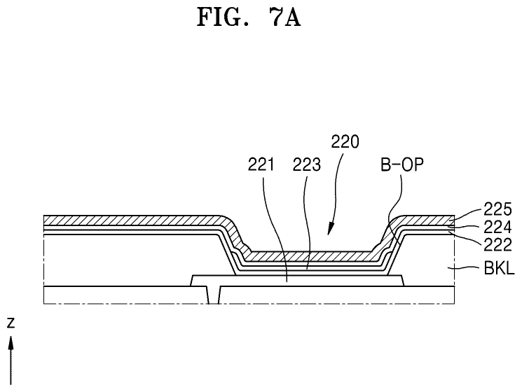

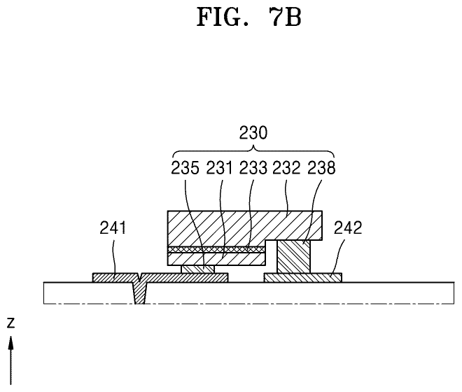

FIG. 7A is a schematic cross-sectional view of a light-emitting element of a stretchable display apparatus according to an embodiment.

Referring to FIG. 7A, the light-emitting element according to an embodiment may include an organic light-emitting diode 220 including an organic material. The organic light-emitting diode 220 may include a first electrode 221 disposed on an insulating layer, a second electrode 225 facing the first electrode 221, and an emission layer 223 arranged between the first electrode 221 and the second electrode 225. A first functional layer 222 may be arranged between the first electrode 221 and the emission layer 223, and a second functional layer 224 may be arranged between the emission layer 223 and the second electrode 225.

The edge of the first electrode 221 may be covered by a bank layer BKL including an insulating material. The bank layer BKL may include an opening B-OP exposing a central portion of the first electrode 221.

The first electrode 221 may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). In some embodiments, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In some embodiments, the first electrode 221 may further include a layer including ITO, IZO, ZnO, AZO, or In₂O₃ above/below the above-described reflective layer.

The emission layer 223 may include a polymer or low molecular weight organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a (semi-) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 225 may further include a layer including ITO, IZO, ZnO, AZO, or In₂O₃ on the (semi-) transparent layer including the above-described material.

FIG. 7B is a schematic cross-sectional view of a light-emitting element of a stretchable display apparatus according to an embodiment.

Referring to FIG. 7B, the light-emitting element according to an embodiment may include an inorganic light-emitting diode 230 including an inorganic material. The inorganic light-emitting diode 230 may include a first semiconductor layer 231, a second semiconductor layer 232, an intermediate layer 233 disposed between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242, which are disposed on the same layer.

In some embodiments, the first semiconductor layer 231 may include a p-type semiconductor layer. The p-type semiconductor layer may be selected from semiconductor materials such as GaN, AlN, AlGaN, InGaN, InN, InAlGaN, and AlInN, having a composition formula of InₓAl_{y}Ga_{1-x-y}N (0≤x≤1, 0≤y≤1, 0≤x+y≤1), and may be doped with a p-type dopant, such as Mg, Zn, Ca, Sr, or Ba.

The second semiconductor layer 232 may include, for example, an n-type semiconductor layer. The n-type semiconductor layer may be selected from semiconductor materials such as GaN, AlN, AlGaN, InGaN, InN, InAlGaN, and AlInN, having a composition formula of InₓAl_{y}Ga_{1-x-y}N (0≤x≤1, 0≤y≤1, 0≤x+y≤1), and may be doped with an n-type dopant, such as Si, Ge, or Sn.

The intermediate layer 233 is a region in which electrons and holes recombine, and, as the electrons and the holes recombine, the recombination of the electrons and the holes transitions to a lower energy level and may generate light having a corresponding wavelength. The intermediate layer 233 may include, for example, a semiconductor material having a composition formula of InₓAl_{y}Ga_{1-x-y}N (0≤x≤1, 0≤y≤1, 0≤x+y≤1), and may be formed to have a single quantum well structure or a multi quantum well (MQW) structure. Alternatively, the intermediate layer 233 may have a quantum wire structure or a quantum dot structure.

FIG. 7B illustrates that the first semiconductor layer 231 includes a p-type semiconductor layer and the second semiconductor layer 232 includes an n-type semiconductor layer, but the disclosure is not limited thereto. In some embodiments, the first semiconductor layer 231 may include an n-type semiconductor layer, and the second semiconductor layer 232 may include a p-type semiconductor layer.

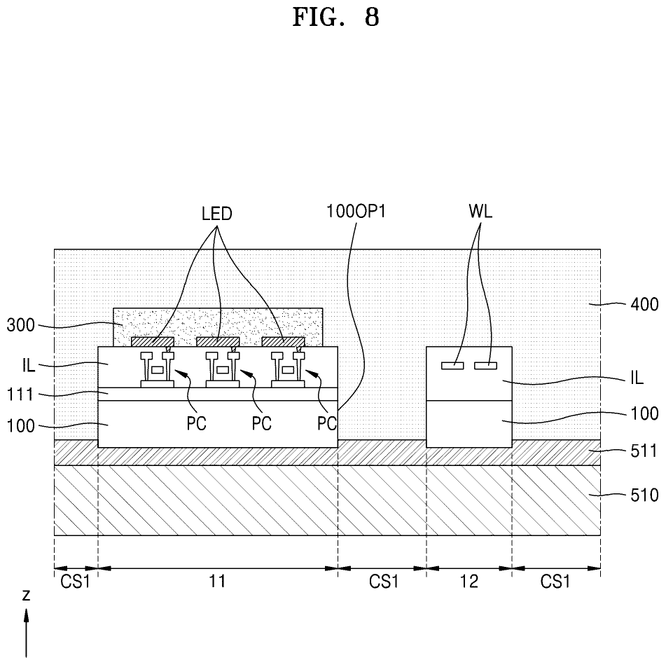

FIG. 8 is a schematic cross-sectional view of a stretchable display apparatus according to an embodiment. The same reference numerals in FIGS. 5 and 8 denote the same members.

Referring to FIG. 8, the stretchable display apparatus may include a plurality of first island portions 11 (hereinafter, island portion) spaced apart from each other, the first bridge portion 12 (hereinafter, bridge portion) connecting the plurality of island portions 11, the substrate 100 including an opening 100OP1 arranged between the plurality of island portions 11, the light-emitting element LED arranged in each of the plurality of island portions 11, the first encapsulation layer 300 sealing the light-emitting element LED, and a second encapsulation layer 400 sealing the plurality of island portions 11 and the bridge portion 12 and filling at least a portion of an upper portion of the opening 100OP1. In addition, the stretchable display apparatus may include a lower encapsulation layer 510 disposed under the substrate 100, and a lower adhesive layer 511 arranged between the substrate 100 and the lower encapsulation layer 510. The lower adhesive layer 511 may fill at least a portion of a lower portion of the opening 100OP1.

The first encapsulation layer 300 may be a member for sealing the light-emitting element LED disposed on the island portion 11. The first encapsulation layer 300 may protect the light-emitting element LED from an external force or external air such as moisture. The first encapsulation layer 300 may be disposed in each of the plurality of island portions 11 to individually seal the plurality of island portions 11.

The first encapsulation layer 300 may include an organic material such as resin. The first encapsulation layer 300 may include polymethyl methacrylate (PMMA), polycarbonate, polystyrene (PS), acrylic resin, epoxy resin, polyimide, polyethylene, polyethylene sulfonate, polyoxymethylene, polyarylate, hexamethyldisiloxane, etc.

In some embodiments, the first encapsulation layer 300 may include urethane epoxy acrylate. In some embodiments, the first encapsulation layer 300 may include a photosensitive material, for example, a material such as photoresist. The first encapsulation layer 300 may protect the light-emitting element LED, and the modulus of the first encapsulation layer 300 may be greater than that of the second encapsulation layer 400. For example, the modulus of the first encapsulation layer 300 may be greater than or equal to about 10 MPa.

The second encapsulation layer 400 may be disposed entirely on an upper surface of the substrate 100 to seal both the island portion 11 and the bridge portion 12. The second encapsulation layer 400 may fill at least a portion of the opening 100OP1 in the substrate 100.

The modulus of the second encapsulation layer 400 may be less than that of the first encapsulation layer 300. In this regard, the term “modulus” may mean elastic modulus or tensile modulus. Because the second encapsulation layer 400 is disposed entirely on the upper surface of the substrate 100, the second encapsulation layer 400 may include a material that has physical properties that do not prevent the stretchable display apparatus from being deformed.

The modulus of the second encapsulation layer 400 may be less than about 5 MPa. For example, the modulus of the second encapsulation layer 400 may be about 100 kPa to about 5 MPa. The second encapsulation layer 400 may include an organic material with excellent stretchability. For example, the second encapsulation layer 400 may include elastomer, polydimethylsiloxane (PDMS), Ecoplex, organic silicone, etc. When the substrate 100 is stretched or contracted, the second encapsulation layer 400 may be stretched or contracted together with the substrate 100.

In the embodiments, by arranging the second encapsulation layer 400, the elongation property of the stretchable display apparatus may be maintained, external light reflection of the display apparatus may be improved, damage due to compression deformation may be prevented.

When the second encapsulation layer 400 is not arranged, an air gap may exist inside the stretchable display apparatus, and thus, external light may be reflected at an interface of the air gap. In the stretchable display apparatus according to embodiments, the second encapsulation layer 400 may fill an air gap in the substrate 100, and thus, external light reflection at an interface of the air gap may be prevented.

In addition, because the second encapsulation layer 400 fills the opening 100OP1 in the substrate 100, damage to the stretchable display apparatus according to embodiments due to compression deformation may be prevented.

The lower encapsulation layer 510 may be attached to a lower portion of the substrate 100 by the lower adhesive layer 511. The lower encapsulation layer 510 may support the substrate 100. The lower encapsulation layer 510 may include a material having a modulus similar to that of the second encapsulation layer 400. The modulus of the lower encapsulation layer 510 may be less than about 5 MPa. For example, the modulus of the lower encapsulation layer 510 may be about 100 kPa to about 5 MPa. The lower encapsulation layer 510 may include an elongation sheet. The lower encapsulation layer 510 may include an elastomer film, a PDMS film, a silicone film, etc.

The lower adhesive layer 511 may be arranged between the substrate 100 and the lower encapsulation layer 510. The lower adhesive layer 511 may fill at least a portion of the opening 100OP1 in the substrate 100. As the lower adhesive layer 511 fills the lower portion of the opening 100OP1, the lower adhesive layer 511 may have strengthened adhesion to the substrate 100. The lower adhesive layer 511 may include an optically clear adhesive (OCA) material. The lower adhesive layer 511 may include an acrylic, silicone-based, or urethane-based material. The lower adhesive layer 511 may be in direct contact with a lower surface of the substrate 100 and the second encapsulation layer 400.

When the substrate 100 is stretched or contracted, the lower encapsulation layer 510 and the lower adhesive layer 511 may be stretched or contracted together with the substrate 100.

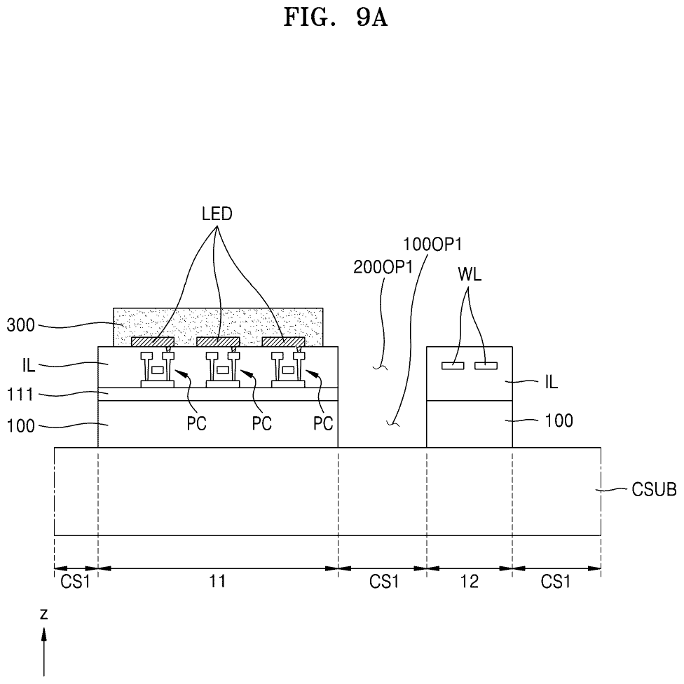

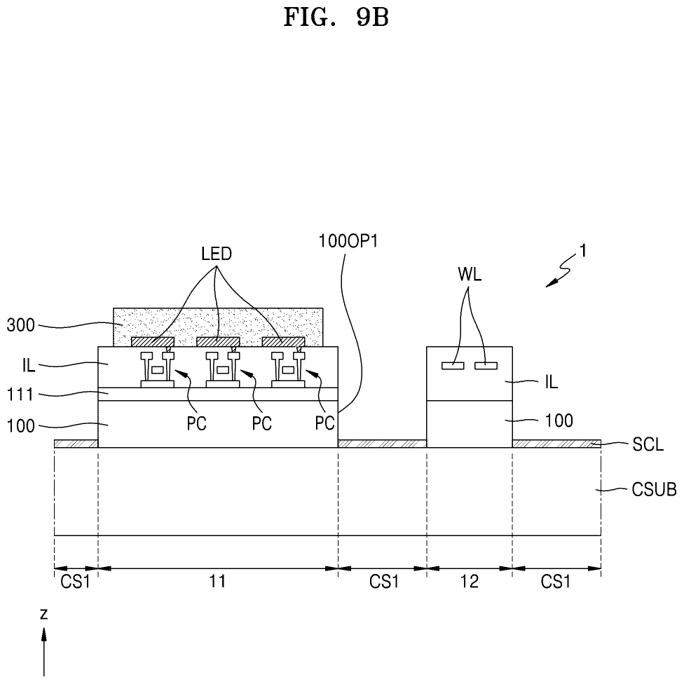

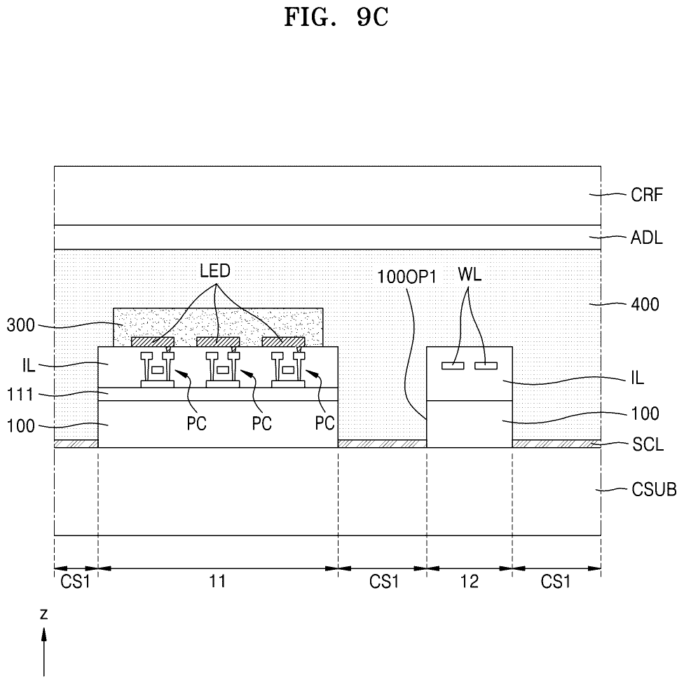

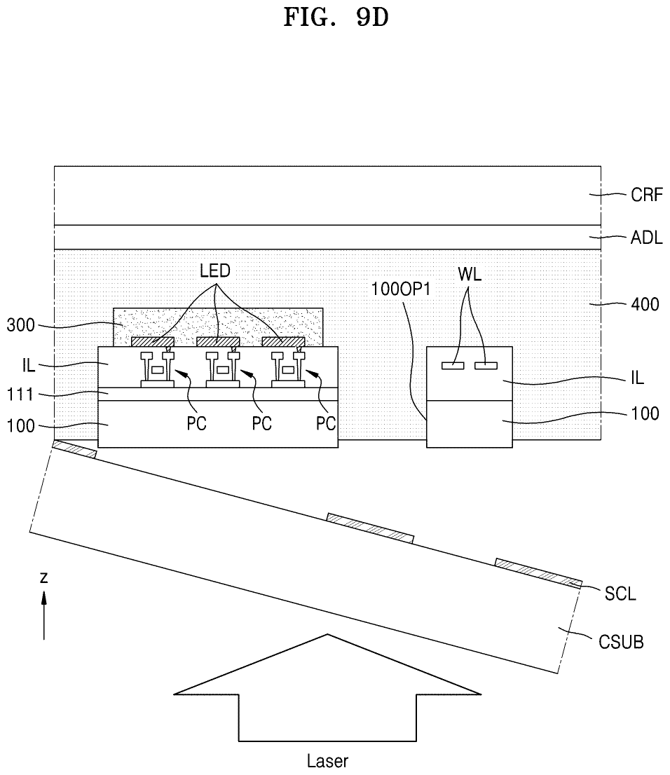

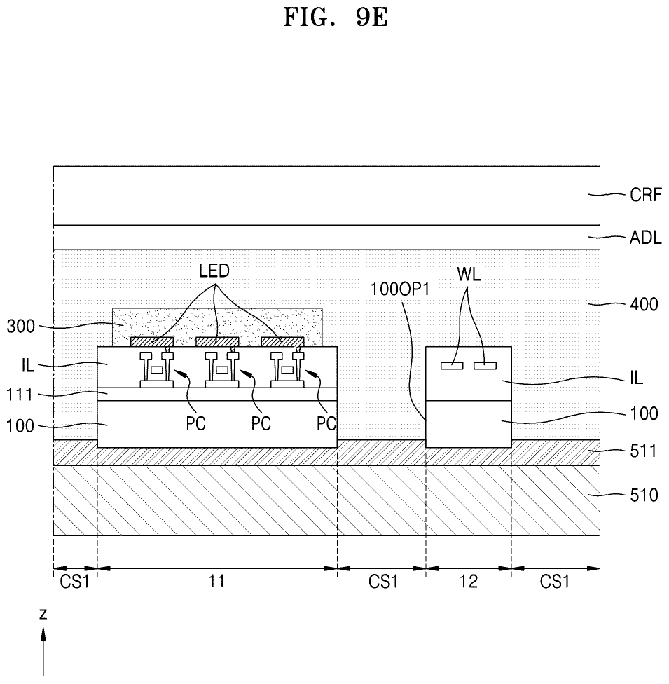

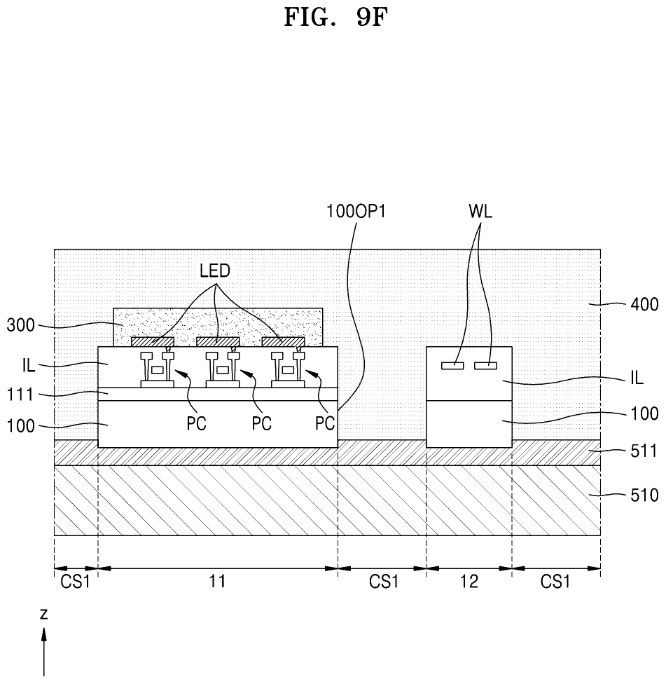

FIGS. 9A to 9F are schematic diagrams showing a method of manufacturing the stretchable display apparatus of FIG. 8.

Referring to FIG. 9A, the pixel driving circuit PC and the wires WL may be formed on the substrate 100 on a carrier substrate CSUB, and the first opening CS1 may be formed in the first opening area. The carrier substrate CSUB supports the substrate 100 when a process is performed and may include glass.

Next, the light-emitting element LED connected to the pixel driving circuit PC is disposed or formed in the island portion 11, and the first encapsulation layer 300 is formed to seal the light-emitting element LED. The first encapsulation layer 300 may include an organic material, and the organic material may be formed via inkjet printing or patterning after coating. The first encapsulation layer 300 may individually seal the island portions 11. The area of the first encapsulation layer 300 may be smaller than the area of one island portions 11.

Referring to FIG. 9B, a sacrificial layer SCL is formed on the carrier substrate CSUB exposed by the first opening CS1. The sacrificial layer SCL may prevent the carrier substrate CSUB and the second encapsulation layer 400 (see FIG. 8) to be formed later from bonding together and secure a space where the lower adhesive layer 511 (see FIG. 8) is formed.

The sacrificial layer SCL may include a material that has a weak bonding force with the second encapsulation layer 400. Alternatively, the sacrificial layer SCL may include a material that has a stronger bonding force with the carrier substrate CSUB than with the second encapsulation layer 400.

In some embodiments, the sacrificial layer SCL may include an organic film. For example, the sacrificial layer SCL may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. In some embodiments, the sacrificial layer SCL may include an inorganic film, such as a silicon oxide, a silicon nitride, amorphous inorganic silicon, etc. The sacrificial layer SCL may be formed by various methods such as coating, inkjet printing, or deposition.

Referring to FIG. 9C, the second encapsulation layer 400 is formed on the carrier substrate CSUB to cover the island portion 11 and the bridge portions 12, and a carrier film CRF is attached onto the second encapsulation layer 400. The carrier film CRF may be attached by an adhesive layer ADL.

The second encapsulation layer 400 may include elastomer, PDMS, Ecoplex, organic silicone, etc. The modulus of the second encapsulation layer 400 may be less than about 5 MPa. The second encapsulation layer 400 may entirely cover the island portion 11 and the bridge portions 12 and may be formed to fill the first opening CS1.

The carrier film CRF may be a protective film that facilitates handling during a process to be performed later, and may include a flexible plastic material, such as polyethylene terephthalate (PET), polyimide, etc. The adhesive layer ADL may be, for example, a pressure sensitive adhesive (PSA), an OCA, etc.

Next, referring to FIG. 9D, the carrier substrate CSUB is separated from the substrate 100. The carrier substrate CSUB may be separated by using a laser lift off method by irradiating a laser beam to a lower portion of the carrier substrate CSUB. Alternatively, the carrier substrate CSUB may be separated from the substrate 100 by using a known physical or chemical method. At this time, the sacrificial layer SCL may be separated together with the carrier substrate CSUB.

Next, referring to FIG. 9E, the lower encapsulation layer 510 is formed under the substrate 100. The lower encapsulation layer 510 may be attached by the lower adhesive layer 511.

The lower encapsulation layer 510 may include an elongation sheet. The lower encapsulation layer 510 may include an elastomer film, a PDMS film, a silicone film, etc. The lower adhesive layer 511 may include an OCA material. The lower adhesive layer 511 may include an acrylic, silicone-based, or urethane-based material.

The lower adhesive layer 511 may be formed on the lower encapsulation layer 510 by a lamination process. A portion of the lower adhesive layer 511 may be formed to fill the opening 100OP1 in the substrate 100 from which the sacrificial layer is removed.

Next, as shown in FIG. 9F, the carrier film CRF and the adhesive layer ADL are removed from the second encapsulation layer 400 to form the stretchable display apparatus as shown in FIG. 8. A polarizing layer and/or touchscreen layer may be formed on the second encapsulation layer 400.

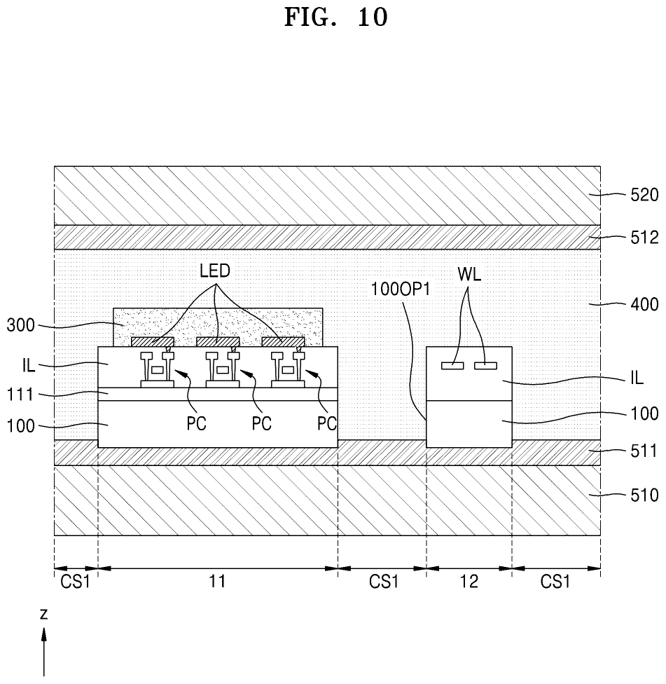

FIG. 10 is a schematic cross-sectional view of a stretchable display apparatus according to an embodiment. The same reference numerals in FIGS. 5, 8, and 10 denote the same members.

Referring to FIG. 10, the stretchable display apparatus may include the plurality of island portions 11 spaced apart from each other, the first bridge portions 12 connecting the plurality of island portions 11 to each other, the substrate 100 including the opening 100OP1 arranged between the plurality of island portions 11, the light-emitting element LED arranged in each of the plurality of island portions 11, the first encapsulation layer 300 sealing the light-emitting element LED, and the second encapsulation layer 400 sealing the plurality of island portions 11 and the bridge portions 12 and filling at least a portion of an upper portion of the opening 100OP1. In addition, the stretchable display apparatus may include the lower encapsulation layer 510 disposed under the substrate 100, and the lower adhesive layer 511 arranged between the substrate 100 and the lower encapsulation layer 510. The lower adhesive layer 511 may fill at least a portion of a lower portion of the opening 100OP1.

In addition, the stretchable display apparatus of FIG. 10 may further include an upper encapsulation layer 520 disposed above the second encapsulation layer 400. The upper encapsulation layer 520 may be attached to the second encapsulation layer 400 by an upper adhesive layer 512.

The upper encapsulation layer 520 may prevent external foreign substances, etc. from penetrating into the stretchable display apparatus. The upper encapsulation layer 520 may include a material having a modulus similar to that of the second encapsulation layer 400. The modulus of the upper encapsulation layer 520 may be less than about 5 MPa. For example, the modulus of the upper encapsulation layer 520 may be about 100 kPa to about 5 MPa. The upper encapsulation layer 520 may include an elongation sheet. The upper encapsulation layer 520 may include an elastomer film, a PDMS film, a silicone film, etc. The upper encapsulation layer 520 may include a material the same as that of the lower encapsulation layer 510.

The upper adhesive layer 512 may be arranged between the second encapsulation layer 400 and the upper encapsulation layer 520. The upper adhesive layer 512 may include an OCA material. The upper adhesive layer 512 may include an acrylic, silicone-based, or urethane-based material. The upper adhesive layer 512 may be in direct contact with the second encapsulation layer 400.

When the substrate 100 is stretched or contracted, the upper encapsulation layer 520 and the upper adhesive layer 512 may be stretched or contracted together with the substrate 100.

The upper encapsulation layer 520 and the upper adhesive layer 512 are formed instead of the carrier film CRF and the adhesive layer ADL of FIG. 9C, and thus, may act as a carrier film, and may remain without being removed later. The upper encapsulation layer 520 and the upper adhesive layer 512 may be formed by a laminating process.

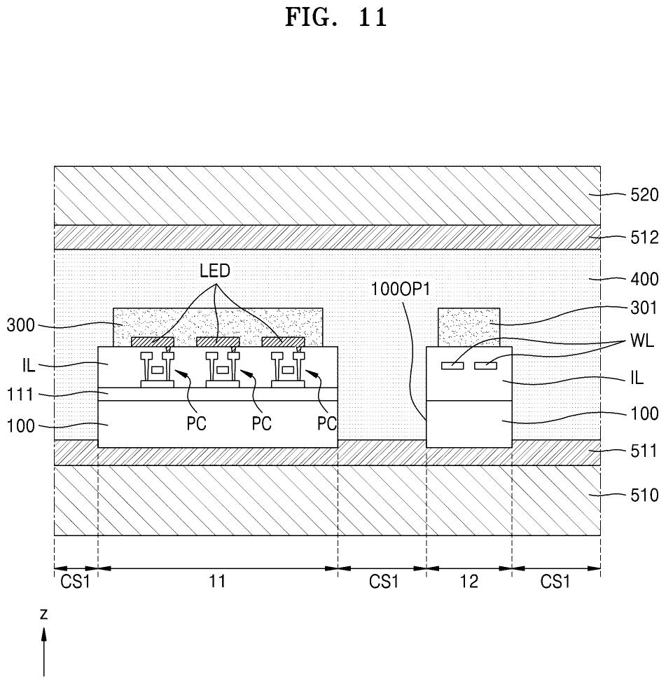

FIG. 11 is a schematic cross-sectional view of a stretchable display apparatus according to an embodiment. The same reference numerals in FIGS. 10 and 11 denote the same members.

Referring to FIG. 11, a dummy-encapsulation layer 301 may be arranged in the bridge portions 12 of the stretchable display apparatus. The dummy-encapsulation layer 301 may disperse pressure applied during a lamination process of forming the lower encapsulation layer 510 and/or the upper encapsulation layer 520.

When there is no dummy-encapsulation layer 301, the first encapsulation layer 300 protrudes only on the island portion 11, and thus, an external force may be concentrated on the island portion 11. In the present embodiment, the dummy-encapsulation layer 301 is arranged in the bridge portions 12 to disperse such an external force.

The height of the dummy-encapsulation layer 301 may be the same as or similar to the height of the first encapsulation layer 300. The dummy-encapsulation layer 301 may include a material the same as that of the first encapsulation layer 300. The dummy-encapsulation layer 301 may include an organic material such as resin. The dummy-encapsulation layer 301 may include PMMA, polycarbonate, PS, acrylic resin, epoxy resin, polyimide, polyethylene, polyethylene sulfonate, polyoxymethylene, polyarylate, hexamethyldisiloxane, etc.

In some embodiments, the dummy-encapsulation layer 301 may include urethane epoxy acrylate. In some embodiments, the dummy-encapsulation layer 301 may include a photosensitive material, for example, a material such as photoresist. The modulus of the dummy-encapsulation layer 301 may be greater than or equal to about 100 MPa.

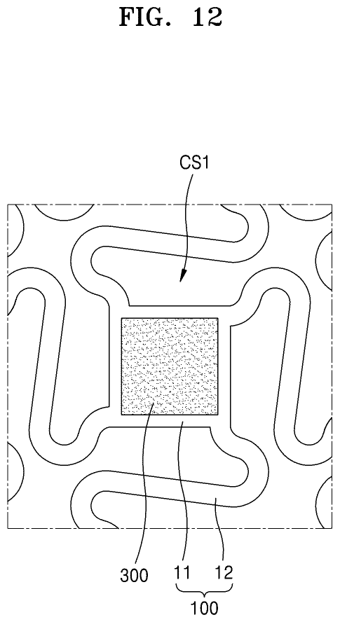

FIGS. 12 to 14 are schematic plan views of a display apparatus according to embodiments. In detail, FIGS. 12 to 14 show the arrangement of a first encapsulation layer and a dummy-encapsulation layer.

Referring to FIG. 12, the first encapsulation layer 300 may be arranged to correspond to the shape of the island portion 11. The first encapsulation layer 300 may be provided to have a quadrangular shape. The area of the first encapsulation layer 300 may be smaller than the area of the island portion 11. Referring to FIG. 12, the dummy-encapsulation layer may not be arranged in the bridge portions 12.

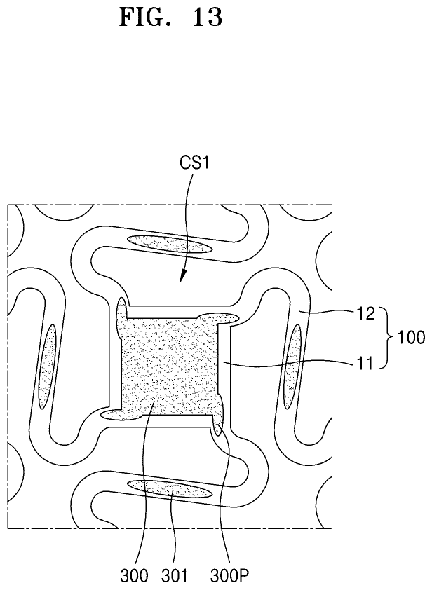

Referring to FIG. 13, the first encapsulation layer 300 may be arranged in the island portion 11. The first encapsulation layer 300 may be arranged to correspond to the shape of the island portion 11 and may include a protrusion 300P that protrudes in an area where the island portion 11 and the bridge portions 12 are connected to each other in a plan view.

The dummy-encapsulation layer 301 may be provided to have an oval shape in the center of the bridge portions 12. However, the disclosure is not limited thereto. The dummy-encapsulation layer 301 may be provided to have a quadrangular shape in the center of the bridge portions 12 or may be provided to have a plurality of circular shapes.

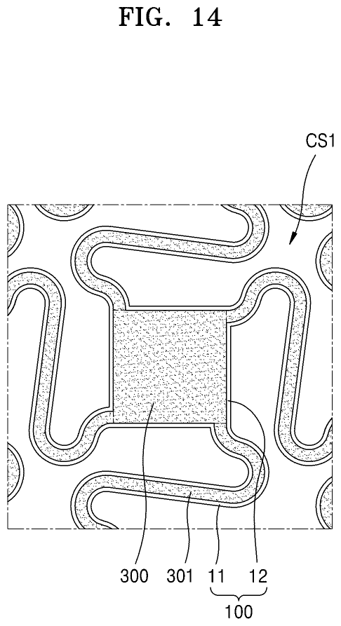

Referring to FIG. 14, the first encapsulation layer 300 and the dummy-encapsulation layer 301 may be integrally formed. The first encapsulation layer 300 and the dummy-encapsulation layer 301 may be entirely arranged to correspond to the shapes of the island portion 11 and the bridge portions 12.

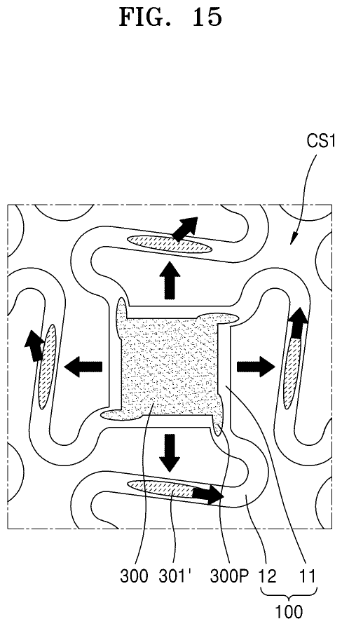

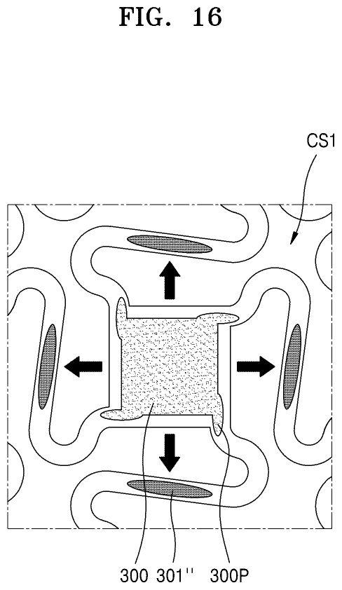

FIGS. 15 and 16 are schematic plan views of a display apparatus according to embodiments.

Referring to FIG. 15, the first encapsulation layer 300 may be arranged in the island portion 11, and a dummy-encapsulation layers 301′ may be arranged in the bridge portions 12. The dummy-encapsulation layers 301′ may include a haze component that scatters or diffuses light. For example, the dummy-encapsulation layers 301′ may include reflectors or scattering particles. For example, the dummy-encapsulation layers 301′ may include titanium oxide (TiO₂) or metal particles which is dispersed in an organic base. In some embodiments, the first encapsulation layer 300 may also include a haze component.

Accordingly, light emitted from the island portion 11 and directed toward the bridge portions 12 may be diffused by the dummy-encapsulation layers 301′ arranged in the bridge portions 12.

Referring to FIG. 16, the first encapsulation layer 300 may be arranged in the island portion 11, and a dummy-encapsulation layers 301″ may be arranged in the bridge portions 12. In the present embodiment, the first encapsulation layer 300 may include a material that emits a red color, a green color, or a blue color. The first encapsulation layer 300 may act as a color filter. In this case, the dummy-encapsulation layers 301″ may include a light-absorbing material to reduce light reflectance. The dummy-encapsulation layers 301″ may be a member for improving color purity and contrast, as a black matrix.

The dummy-encapsulation layers 301″ may include at least one of a black pigment, a black dye, or black particles which is dispersed in an organic base. In some embodiments, the dummy-encapsulation layers 301″ may include Cr, CrOx, Cr/CrOx, Cr/CrOx/CrNy, resin (a carbon pigment or an RGB mixed pigment), graphite, or a non-Cr-based material. Because the first encapsulation layer 300 acts as a color filter and the dummy-encapsulation layers 301″ acts as a black matrix, the light purity of the stretchable display apparatus may be increased.

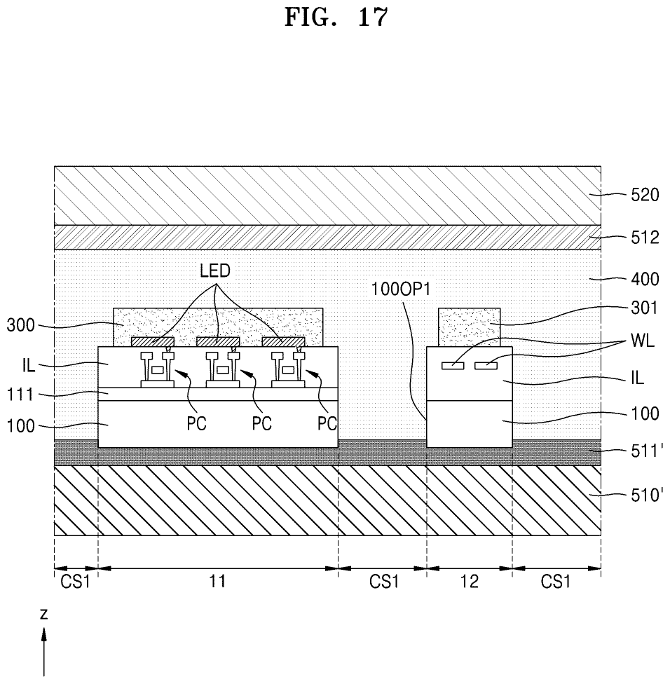

FIGS. 17 to 19 are schematic cross-sectional views of a display apparatus according to embodiments. The same reference numerals in FIGS. 11 and 17 to 19 denote the same members.

Referring to FIG. 17, a lower adhesive layer 511′ and/or a lower encapsulation layer 510′ may include a light-blocking material. The lower adhesive layer 511′ may include at least one of a black pigment, a block dye, or black particles in addition to an acrylic, silicone-based, urethane-based adhesive material.

The modulus of the lower encapsulation layer 510′ may be less than about 5 MPa. For example, the modulus of the lower encapsulation layer 510′ may be about 100 kPa to about 5 MPa. The lower encapsulation layer 510′ may include an elongation sheet. The lower encapsulation layer 510′ may include an elastomer film, a PDMS film, or a silicone film, each including a light-blocking material. The light-blocking material may be at least one of a black pigment, a black dye, or black particles. For example, the light-blocking material may be Cr, CrOx, Cr/CrOx, Cr/CrOx/CrNy, resin (a carbon pigment or an RGB mixed pigment), graphite, or a non-Cr-based material. Accordingly, the reflectance of the stretchable display apparatus may be reduced.

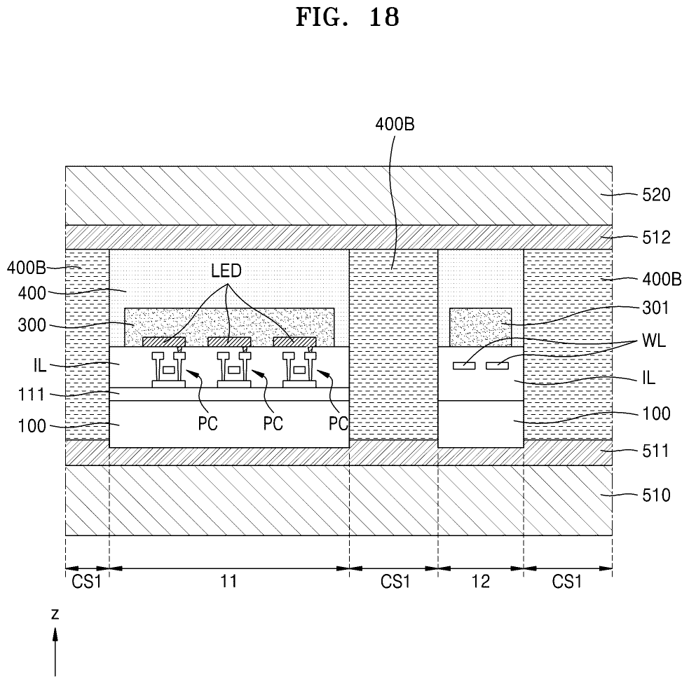

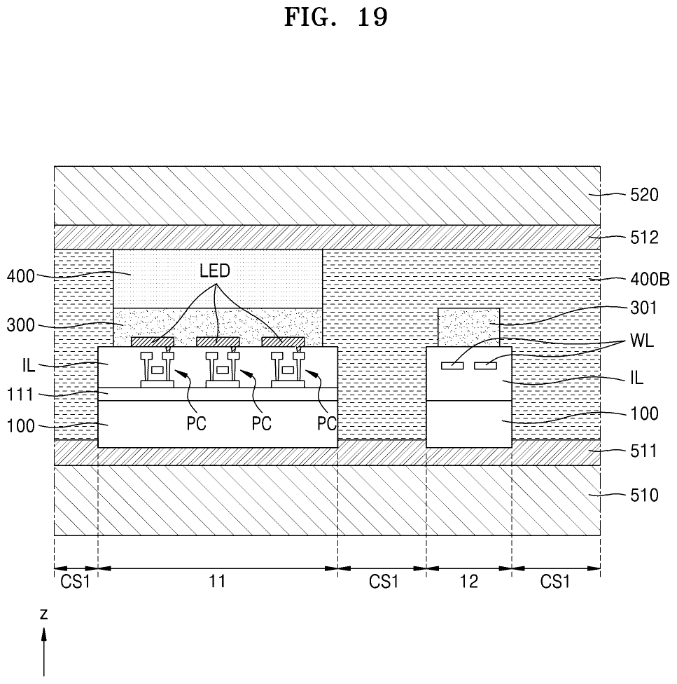

Referring to FIGS. 18 and 19, the second encapsulation layer 400 may include a light-blocking region 400B. The light-blocking region 400B may be a region including a light-blocking material. The light-blocking material may be at least one of a black pigment, a black dye, or black particles. For example, the light-blocking material may be Cr, CrOx, Cr/CrOx, Cr/CrOx/CrNy, resin (a carbon pigment or an RGB mixed pigment), graphite, or a non-Cr-based material.

As shown in FIG. 18, the light-blocking region 400B may be arranged in a region corresponding to the opening 100OP1 in the substrate 100. Alternatively, as shown in FIG. 19, the light-blocking region 400B may be formed in a region other than a region where the first encapsulation layer 300 is arranged. In other words, the light-blocking region 400B may be formed to correspond to the first opening CS1 and the bridge portions 12. Because the second encapsulation layer 400 includes the light-blocking region 400B, the external light reflectance of the stretchable display apparatus may be reduced.

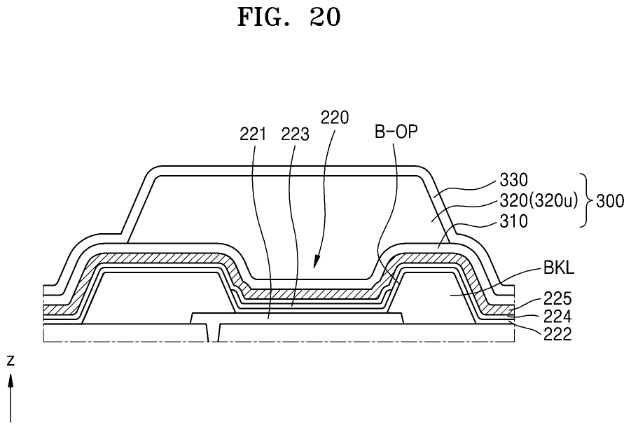

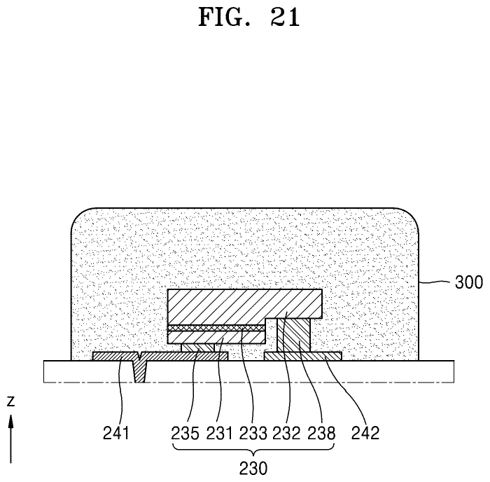

FIGS. 20 and 21 are each a schematic cross-sectional view of a first encapsulation layer which encapsulates a light-emitting element of a stretchable display apparatus according to an embodiment. The same reference numerals in FIGS. 7A, 7B, 20, and 21 denote the same members.

Referring to FIG. 20, the light-emitting element of the stretchable display apparatus according to an embodiment may be the organic light-emitting diode 220. In this case, the first encapsulation layer 300 may include a stack of a first inorganic encapsulation layer 310, an organic encapsulation layer 320, and a second inorganic encapsulation layer 330.

Each of the first inorganic encapsulation layer 310 and the second inorganic encapsulation layer 330 may include at least one inorganic insulating material such as an aluminum oxide, a titanium oxide, a tantalum oxide, a hafnium oxide, a zinc oxide, a silicon oxide, a silicon nitride, or a silicon oxynitride, and may be formed by chemical vapor deposition (CVD), etc. The first inorganic encapsulation layer 310 and the second inorganic encapsulation layer 330 may be formed to cover a side surface of the first opening CS1 (see FIG. 8).

Because the first inorganic encapsulation layer 310 is a conformal layer which is formed along a structure disposed below the first inorganic encapsulation layer 310, an upper surface thereof is not flat. The organic encapsulation layer 320 covers the first inorganic encapsulation layer 310, and unlike the first inorganic encapsulation layer 310, may have an approximately flat upper surface. In detail, an upper surface of the organic encapsulation layer 320 disposed on the organic light-emitting diode 220, that is the light-emitting element, may have an approximately flat upper surface. In addition, the organic encapsulation layer 320 may relieve stress generated in the first and second inorganic encapsulation layers 310 and 330.

The organic encapsulation layer 320 may include PMMA, polycarbonate, PS, acrylic resin, epoxy resin, polyimide, polyethylene, polyethylene sulfonate, polyoxymethylene, polyarylate, hexamethyldisiloxane, etc.

In the present embodiment, the organic encapsulation layer 320 may include unit organic encapsulation layers 320u disposed in an area corresponding to each of the island portions 11. In other words, the planar area of the unit organic encapsulation layer 320u may be smaller than the area of the island portion 11 of the substrate 100. Accordingly, the first inorganic encapsulation layer 310 and the second inorganic encapsulation layer 330 may be in direct contact with each other on at the periphery of the island portions 11 to individually encapsulate each of components arranged in the island portion 11. Meanwhile, the modulus of the first encapsulation layer 300 may be greater than the modulus of the second encapsulation layer 400 (see FIG. 8).

Referring to FIG. 21, the light-emitting element of the stretchable display apparatus according to an embodiment may be the inorganic light-emitting diode 230. In this case, the first encapsulation layer 300 may include only an organic material. Because the inorganic light-emitting diode 230 is less vulnerable to moisture than an organic light-emitting diode, an inorganic encapsulation layer may not be introduced.

The first encapsulation layer 300 may include an organic material such as resin. The first encapsulation layer 300 may include PMMA, polycarbonate, PS, acrylic resin, epoxy resin, polyimide, polyethylene, polyethylene sulfonate, polyoxymethylene, polyarylate, hexamethyldisiloxane, etc.

In some embodiments, the first encapsulation layer 300 may include urethane epoxy acrylate. In some embodiments, the first encapsulation layer 300 may include a photosensitive material, for example, a material such as photoresist. Meanwhile, the modulus of the first encapsulation layer 300 may be greater than that of the second encapsulation layer 400. The first encapsulation layer 300 may individually seal the island portions 11.

Meanwhile, even when the light-emitting element is the inorganic light-emitting diode 230, the first encapsulation layer 300 may include a stack of a first inorganic encapsulation layer, an organic encapsulation layer, and a second inorganic encapsulation layer, as shown in FIG. 20.

The stretchable display apparatus 1 according to the above-described embodiments may be used in various electronic devices capable of providing an image. In this regard, the electronic devices refer to devices capable of providing a certain image by using electricity.

The stretchable display apparatus 1 according to the above-described embodiments may be used in various electronic devices capable of providing an image. In this regard, the electronic devices refer to devices capable of providing a certain image by using electricity.

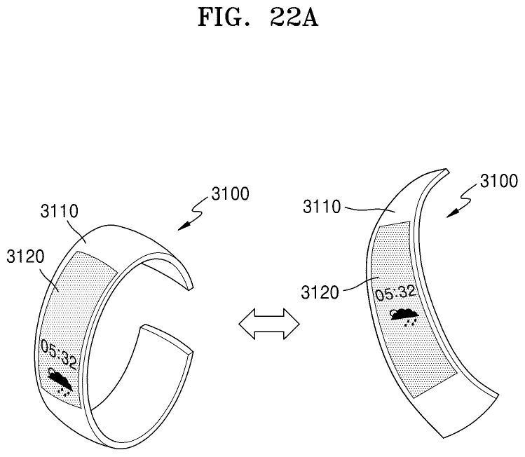

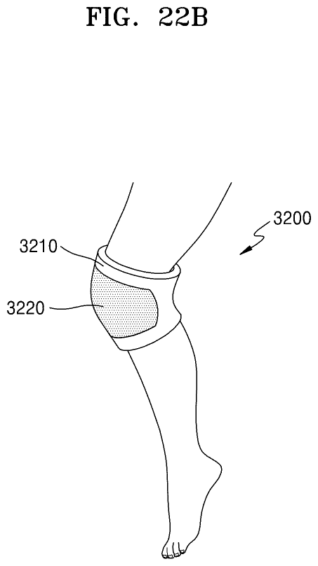

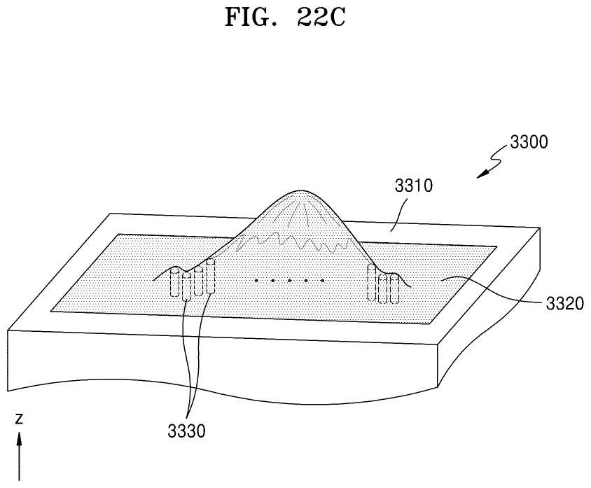

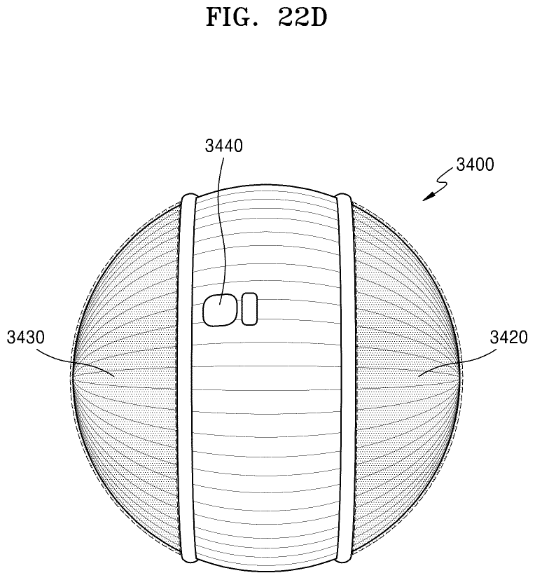

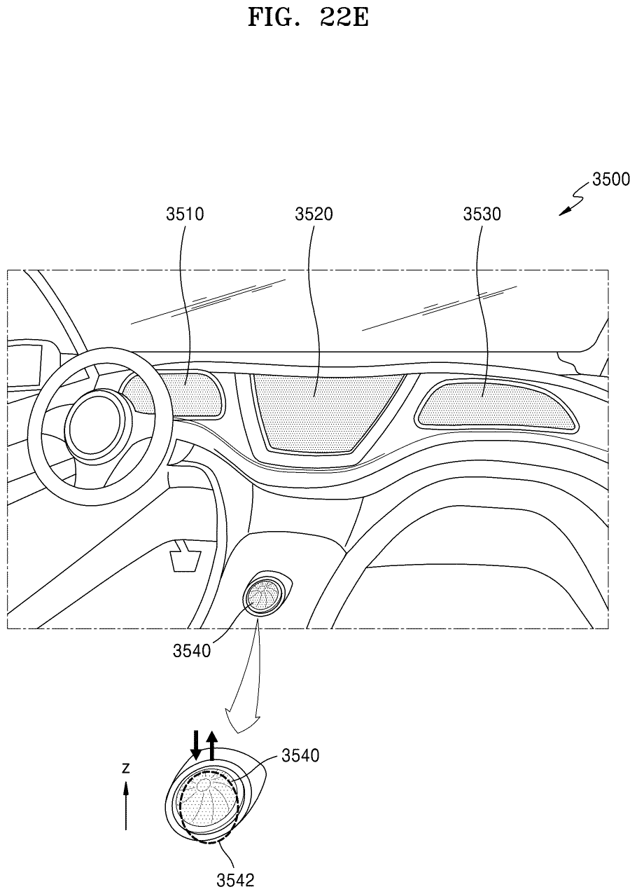

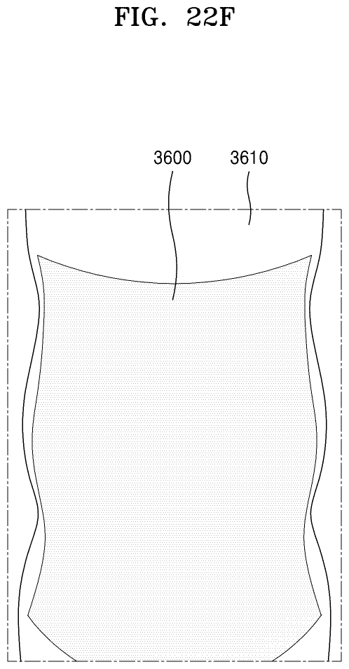

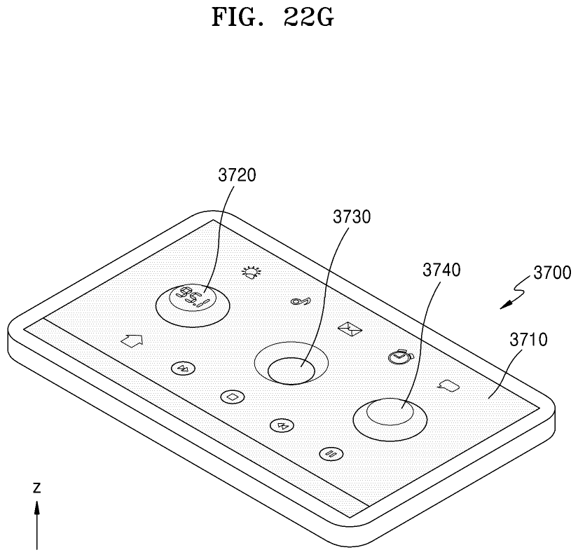

FIGS. 22A to 22G are each schematic perspective view of embodiments of an electronic device including a stretchable display apparatus according to an embodiment.

Referring to FIG. 22A, the stretchable display apparatus according to an embodiment may be used in a wearable electronic device 3100 that may be worn on a portion of a user's body. The wearable electronic device 3100 may include a body portion 3110 and a display unit 3120 provided on the body portion 3110. The stretchable display apparatus according to embodiments may be used as the display unit 3120 of the wearable electronic device 3100. As shown in FIG. 22A, the wearable electronic device 3100 may be deformable. In an embodiment, the wearable electronic device 3100 may be used as a smart watch or a smartphone depending on a user's choice.

FIG. 22B illustrates a medical electronic device 3200. In an embodiment, the medical electronic device 3200 may include a body portion 3210 and a light-emitting portion 3220. The stretchable display apparatus according to embodiments may be used as the light-emitting portion 3220 of the medical electronic device 3200. The light-emitting portion 3220 may emit light (for example, infrared light, visible light, etc.) of a certain wavelength band to a patient's body. In an embodiment, the body portion 3210 may have a stretchable fiber material and may have a structure that may be worn on a user's body.

FIG. 22C illustrates an educational electronic device 3300. In an embodiment, the educational electronic device 3300 may include a display unit 3320 provided in a frame 3310. The display unit 3320 may use a stretchable display apparatus according to embodiments. The display unit 3320 may provide an image such as a sea with waves, a mountain covered by snow, or a volcano with flowing lava, and at this time, the display unit 3320 may be stretched in a height direction (for example, z direction) to reflect the heights of the waves, the mountain, or the volcano. In some embodiments, a portion of the display unit 3320 may show movement of lava in three dimensions by sequentially changing the height along a direction in which the lava flows. The educational electronic device 3300 may include a plurality of pins (or stroke units) 3330 disposed on a rear surface of the display unit 3320 such that the display unit 3320 is stretched in the height direction. As the pins 3330 move in a third direction (for example, z direction or −z direction), an image displayed on the display unit 3320 may be implemented to have a three-dimensional height. FIG. 22C illustrates the educational electronic device 3300, but its use is not limited as long as the educational electronic device 3300 provides certain image information.

The electronic devices shown in FIGS. 22A to 22C may have shapes that may be variable, but the disclosure is not limited. As in embodiments to be described later, a stretchable display apparatus according to embodiments may be used in an electronic device in which a portion (for example, screen) that may display an image is fixed.

FIG. 22D shows a robot 3400 as an electronic device according to an embodiment. The robot 3400 may recognize movement or objects by using a camera unit 3440 and may display a certain image to a user via display units 3420 and 3430. In some embodiments, the stretchable display apparatuses according to an embodiment may be stretched in various directions as described above, and thus, may be assembled into a body frame having a hemispherical shape. Therefore, the robot 3400 may include the display units 3420 and 3430 each having a hemispherical shape.

FIG. 22E shows a vehicle display device 3500 as an electronic device according to an embodiment. The vehicle display device 3500 may include a cluster 3510, a center information display (CID) 3520, and/or a passenger-seat display 3530. The stretchable display apparatus according to an embodiment may be stretched in various directions and thus may be used in the cluster 3510, the CID 3520, and/or the passenger-seat display 3530 regardless of the shape of an internal frame of a vehicle.

FIG. 22E shows that the cluster 3510, the CID 3520, and/or the passenger-seat display 3530 are separated from each other, but the disclosure is not limited thereto. In some embodiments, two or more selected from the cluster 3510, the CID 3520, and the passenger-seat display 3530 may be integrally connected.

In some embodiments, the vehicle display device 3500 may include a button 3540 that may display a certain image. Referring to an enlarged view of FIG. 22E, the button 3540 having a hemispherical shape may include an object 3542 that provides feelings of using the button 3540 while the object 3542 moves in a z direction or −z direction, and a stretchable display apparatus disposed on the object 3542. In some embodiments, when the object 3542 has a three-dimensionally rounded surface, the stretchable display apparatus may also have a three-dimensionally rounded surface.

FIG. 22F shows that an electronic device according to an embodiment is an electronic device 3600 used for advertisement or exhibition. In some embodiments, the electronic device 3600 used for advertisement or exhibition may be installed on a fixed structure 3610, such as a wall or a pillar. When the structure 3610 includes an uneven surface as shown in FIG. 22F, the electronic device 3600 used for advertisement or exhibition may also be arranged along the uneven surface of the structure 3610. In some embodiments, the electronic device 3600 used for advertisement or exhibition may be installed on the structure 3610 by using a heat shrink film, etc.

FIG. 22G shows that an electronic device according to an embodiment is a controller 3700. The controller 3700 may include an image-type button. For example, the controller 3700 may include first to third button regions 3720, 3730, and 3740 in which a partial region of a display unit 3710 protrudes in a z direction or in a −z direction (or is depressed in the z direction). In some embodiments, the first and third button regions 3720 and 3740 may protrude in the z direction, and the second button region 3730 may protrude in the −z direction (or may be depressed in the z direction).

According to an embodiment, there may be provided a display apparatus that may prevent damage caused by concentration of stress and may be stretched/contracted in various directions.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate including a plurality of island portions spaced apart from each other, a plurality of bridge portions connecting the plurality of island portions to each other, and a plurality of openings disposed between the plurality of island portions;
at least one light-emitting element arranged in each of the plurality of island portions;
a plurality of first encapsulation layers disposed on the plurality of island portions, respectively, each of the plurality of first encapsulation layers sealing the at least one light-emitting element;
a second encapsulation layer disposed on the plurality of first encapsulation layers to cover the plurality of island portions and the plurality of bridge portions and filling at least upper portions of the plurality of openings;
a lower encapsulation layer disposed under the substrate; and
a lower adhesive layer arranged between the lower encapsulation layer and the substrate,
wherein the lower adhesive layer fills at least lower portions of the plurality of openings.

2. The display apparatus of claim 1, wherein a modulus of the second encapsulation layer is less than a modulus of the first encapsulation layer.

3. The display apparatus of claim 2, wherein the modulus of the second encapsulation layer is about 100 kPa to about 5 MPa.

4. The display apparatus of claim 1, wherein a modulus of the lower encapsulation layer is less than a modulus of the first encapsulation layer.

5. The display apparatus of claim 1, further comprising:
an upper encapsulation layer disposed above the second encapsulation layer; and
an upper adhesive layer arranged between the upper encapsulation layer and the second encapsulation layer.

6. The display apparatus of claim 5, wherein a modulus of the upper encapsulation layer is less than a modulus of the first encapsulation layer.

7. The display apparatus of claim 1, further comprising a plurality of dummy-encapsulation layers arranged in the plurality of bridge portions,
wherein the plurality of dummy-encapsulation layers include a material the same as a material of the first encapsulation layer.

8. The display apparatus of claim 7, wherein the plurality of dummy-encapsulation layers are arranged to correspond to centers of the plurality of bridge portions and are arranged to be spaced apart from the plurality of first encapsulation layers.

9. The display apparatus of claim 7, wherein the plurality of dummy-encapsulation layers are integrally provided with the plurality of first encapsulation layers.

10. The display apparatus of claim 7, wherein the plurality of dummy-encapsulation layers include reflectors or scattering particles.

11. The display apparatus of claim 7, wherein the plurality of first encapsulation layers include a material that emits a red color, a green color, or a blue color, and the plurality of dummy-encapsulation layers include a light-blocking material.

12. The display apparatus of claim 1, wherein a planar area of each of the plurality of first encapsulation layers is smaller than an area of each of the plurality of island portions.

13. The display apparatus of claim 1, wherein at least one of the lower adhesive layer and the lower encapsulation layer includes a light-blocking material.

14. The display apparatus of claim 1, wherein the second encapsulation layer includes a plurality of light-blocking regions including a light-blocking material and disposed in areas corresponding to the plurality of openings.

15. The display apparatus of claim 14, wherein the plurality of light-blocking regions are disposed in areas corresponding to the plurality of bridge portions.

16. The display apparatus of claim 1, wherein the at least one light-emitting element is an organic light-emitting diode including an organic material, and
wherein each of the plurality of first encapsulation layers includes a stack of a first inorganic encapsulation layer, an organic encapsulation layer, and a second inorganic encapsulation layer.

17. The display apparatus of claim 16, wherein a planar area of the organic encapsulation layer is smaller than an area of each of the plurality of island portions.

18. The display apparatus of claim 1, wherein the at least one light-emitting element is an inorganic light-emitting diode including an inorganic material, and
wherein the first encapsulation layer does not include an inorganic material.

19. A display apparatus comprising:
a substrate including a plurality of island portions spaced apart from each other, a plurality of bridge portions connecting the plurality of island portions to each other, and a plurality of openings disposed between the plurality of island portions;
at least one light-emitting element arranged in each of the plurality of island portions;
a plurality of first encapsulation layers disposed on the plurality of island portions, respectively, each of the plurality of first encapsulation layers sealing the at least one light-emitting element;
a second encapsulation layer disposed on the plurality of encapsulating layers to cover the plurality of island portions and the plurality of bridge portions, and filling at least upper portions of the plurality of openings;
a lower encapsulation layer disposed under the substrate; and
a lower adhesive layer arranged between the lower encapsulation layer and the substrate,
wherein a planar area of each of the plurality of first encapsulation layers is smaller than a planar area of each of the plurality of island portions.

20. The display apparatus of claim 19, wherein a modulus of the second encapsulation layer and a modulus of the lower encapsulation layer are each less than a modulus of the first encapsulation layer.

21. The display apparatus of claim 19, further comprising:
an upper encapsulation layer disposed above the second encapsulation layer; and
an upper adhesive layer arranged between the upper encapsulation layer and the second encapsulation layer.

22. The display apparatus of claim 19, further comprising a plurality of dummy-encapsulation layers arranged in the plurality of bridge portions,
wherein the plurality of dummy-encapsulation layers include a material the same as a material of the plurality of first encapsulation layers.

23. The display apparatus of claim 22, wherein the plurality of first encapsulation layers include a material that emits a red color, a green color, or a blue color, and the plurality of dummy-encapsulation layers include a light-blocking material.

24. The display apparatus of claim 19, wherein at least one of the lower adhesive layer and the lower encapsulation layer includes a light-blocking material.

25. The display apparatus of claim 19, wherein the second encapsulation layer includes a plurality of light-blocking regions which include a light-blocking material.
